(19) United States
(12) Patent Application Publication
(10) Pub. No.: US 2012/0052657 A1
(43) Pub. Date: Mar. 1, 2012

(54) METHOD OF FORMING FILM AND SUBSTRATE PROCESSING APPARATUS

(75) Inventors: Tomoshi TANIYAMA, Toyama (JP); Naoto NAKAMURA, Toyama (JP)

(73) Assignee: HITACHI KOKUSAI ELECTRIC INC., Tokyo (JP)

(21) Appl. No.: 13/192,055

(22) Filed: Jul. 27, 2011

(30) Foreign Application Priority Data
Aug. 30, 2010 (JP) 2010-192765

(51) Int. Cl. H01L 21/205; C23C 16/455

(52) U.S. Cl. 438/478; 118/724; 257/E21.101

(57) ABSTRACT

A method of forming a film and a substrate processing apparatus, which can increase the number of substrates to be processed at once in order to improve productivity, are provided. In order to solve the problems, the method of forming a film includes loading a plurality of substrates into a substrate processing region in a processing chamber; and forming a film containing nitrogen and metal on each of the plurality of substrates by heating the substrate processing region in the processing chamber, supplying a nitrogen-containing gas through a first gas supply port installed outside the substrate processing region in the processing chamber, and supplying a metal-containing gas through a second gas supply port installed closer to the substrate processing region than the first gas supply port.

### CROSS-REFERENCE TO RELATED PATENT APPLICATION

This application claims priority to and the benefit of Japanese Patent Application No. 2010-192765 on Aug. 30, 2010, the disclosure of which is incorporated herein by reference.

### BACKGROUND OF INVENTION

1. Field of the Invention

The present invention relates to a method of forming a film and a substrate processing apparatus.

2. Description of the Related Art

In a processing chamber, a substrate is mounted on one susceptor made of silicon carbide (SiC), etc., the susceptor is induction-heated by a high-frequency inductor, etc., and a source gas is supplied into the processing chamber, so that an epitaxial film of a compound semiconductor made of gallium nitride (GaN) can grow under a high temperature (see Patent Document 1).

### PRIOR-ART DOCUMENT

### Patent Document

1. Japanese Patent Laid-open Publication No.: 2009-239250

### SUMMARY OF THE INVENTION

However, when a film is formed on a substrate using an apparatus having such a configuration, there is a limit to the number of substrates to be processed at once.

The present invention is designed to solve such problems, and an object of the present invention is to provide a method of forming a film and a substrate processing apparatus, which are able to increase the number of substrates to be processed at once in order to improve productivity.

In order to solve the problems, according to one aspect of the present invention, there is provided a method of forming a film including: loading a plurality of substrates into a substrate processing region in a processing chamber; and forming a film containing nitrogen and metal on each of the plurality of substrates by heating the substrate processing region in the processing chamber, supplying a nitrogen-containing gas through a first gas supply port installed outside the substrate processing region in the processing chamber, and supplying a metal-containing gas through a second gas supply port installed closer to the substrate processing region than the first gas supply port.

According to one aspect of the present invention, there is also provided a method of forming a film including: loading a plurality of substrate into a substrate processing region in a processing chamber; and forming a film containing silicon, nitrogen and metal on each of the plurality of substrates by heating of the substrate processing region in the processing chamber, supplying a nitrogen-containing gas and a metal-containing gas from an outside of the substrate processing region in the processing chamber, and supplying a silicon-containing gas from an inside of the substrate processing region in the processing chamber.

In addition, according to one aspect of the present invention, there is provided a substrate processing apparatus including: a processing chamber including a substrate processing region and configured to process a plurality of substrates at the substrate processing region; a heating device configured to heat the substrate processing region; a first gas supply system including a first gas supply port, the first gas supply port being configured to supply a nitrogen-containing gas into the processing chamber and installed outside the substrate processing region; a second gas supply system including a second gas supply port, the second gas supply port being installed outside the substrate processing region while being closer to the substrate processing region than the first gas supply port and being configured to supply a metal-containing gas into the processing chamber; and a control unit configured to control the heating device, the first gas supply system and the second gas supply system to form a film containing nitrogen and metal on each of a plurality of substrates in the substrate processing region by heating the substrate processing region, supplying the nitrogen-containing gas through the first gas supply port and supplying the metal-containing gas through the second gas supply port.

According to the present invention, a method of forming a film and a substrate processing apparatus, which are able to increase the number of substrates to be processed at once in order to improve productivity, can be provided.

### BRIEF DESCRIPTION OF THE DRAWINGS

FIG. 1 is a schematic diagram illustrating a processing furnace of a substrate processing apparatus according to a first embodiment of the present invention.

FIG. 2 is a diagram illustrating a configuration of a semiconductor device according to a first embodiment of the present invention.

FIG. 3 is a schematic diagram illustrating a processing furnace of a substrate processing apparatus according to a third embodiment of the present invention.

### DETAILED DESCRIPTION OF THE PREFERRED EMBODIMENTS

For the sake of convenience, the following embodiments are divided into a plurality of sections or embodiments for description, when necessary. However, unless stated explicitly otherwise, these embodiments are clearly related to each other, and thus one embodiment is connected with some or all of modified examples, details and supplementary descriptions of the other embodiment.

Also, when the number (including a number, a value, an amount, a range, etc) of an element is recited in the following embodiments, the present invention is not limited to the specific number, unless specified explicitly otherwise and principally defined as a specific number, and thus a value more or less than the specific number may be used herein.

In the following embodiments, the components (including an element step, etc.) are also not necessary, unless specified explicitly otherwise and principally considered as necessary.

Likewise, when a shape, a positional relationship and the like of a component is recited in the following embodiments, a shape analogous or similar to the shape is included, unless specified explicitly and principally considered otherwise. This also applies to numbers and ranges in the same manner.

Also, in all of the drawings for describing embodiments, like members have like reference numerals, and their re-descriptions are omitted. Also, a plan view may be hatched to facilitate better understanding of the drawings.

### First Embodiment

According to an embodiment for realizing the present invention, a substrate processing apparatus is, for example, configured as devices for performing various processing processes included in a method of manufacturing a light-emitting diode (LED), a light-emitting body, and a semiconductor device (an integrated circuit (IC), etc). In the following description, a vertical substrate processing apparatus into which a technical idea of the present invention is introduced will be described, which performs a technique for growing crystal, a technique for forming a compound semiconductor film, a film-forming process using an epitaxial growth method, a film-forming process using a chemical vapor deposition (CVD) method, or an oxidation or diffusion process on a substrate (a wafer). In this embodiment, a batch-type substrate processing apparatus configured to process a plurality of substrates at once will be particularly described.

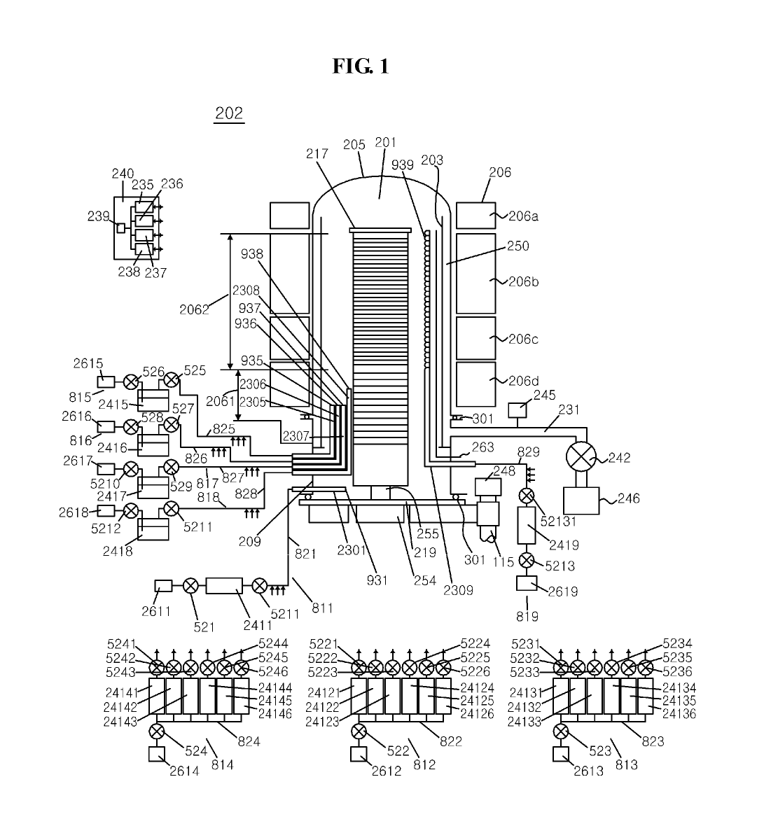

According to this first embodiment, a processing furnace 202 of the substrate processing apparatus will be described with reference to the drawings. FIG. 1 is a cross-sectional view schematically illustrating the processing furnace 202 of the substrate processing apparatus according to this first embodiment, and surroundings of the processing furnace 202.

As shown in FIG. 1, the processing furnace 202 includes a heating device 206 configured to heat a plurality of substrates in a processing chamber. The heating device 206 is formed in a cylindrical shape. A heating element from which heat is emitted by a resistive heating method is provided in the heating device 206. Also, the heating device 206 may be provided with a heating element from which heat is emitted by a lamp heating method, instead of the heating element from which the heat is emitted by the resistive heating method.

The heating device 206 is configured to be controllable at four heating regions (heating zones), respectively. Among the heating zones, a lowest region is an L zone (corresponding to a heating device 206d), a region arranged directly above the L zone is a CL zone (corresponding to a heating device 206c), a region arranged directly above the CL zone is a CU zone (corresponding to a heating device 206b), and a region arranged directly above the CU zone is a U zone (corresponding to a heating device 206a).

At an inner part of the heating device 206, an outer tube 205 serving as a reaction tube configured to constitute a reaction container concentrically with the heating device 206 is installed. The outer tube 205 is made of a quartz (SiO₂) material serving as a heat-resistant material, and is formed in a cylindrical shape with its upper end closed and its lower end open. An inner tube 203 is installed at an inner part of the outer tube 205. The inner tube 203 is made of a quartz (SiO₂) material serving as a heat-resistant material, and is formed in a cylindrical shape with its upper and lower ends open. A processing chamber 201 is formed at an inner part of the inner tube 203.

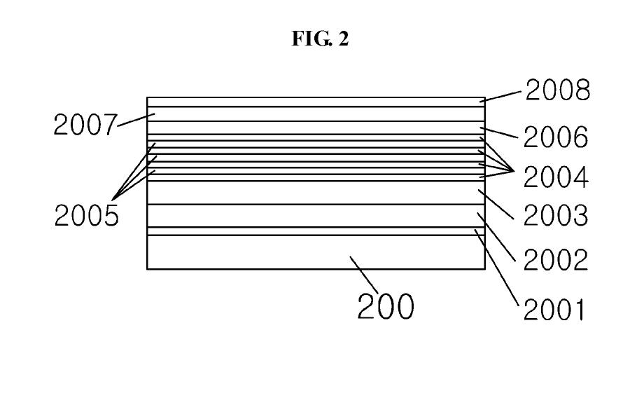

A wafer (200 in FIG. 2) serving as a substrate made of a sapphire material is accommodated in the processing chamber 201 by means of a boat 217 serving as a substrate-holding unit to be described later in a state where the wafers are stacked at predetermined distances in a vertical direction with respect to a main surface of the wafer 200.

At a lower portion of the outer tube 205, a manifold 209 is arranged concentrically with the outer tube 205. The manifold 209 is, for example, made of quartz (SiO₂), stainless steel, etc., and is formed in a cylindrical shape with its upper and lower ends open. The manifold 209 is installed to support the outer tube 205 and the inner tube 203. Also, an O-ring 301 serving as a seal member is installed between the manifold 209 and the outer tube 205. As the manifold 209 is supported by a holder (not shown), the outer tube 205 is installed in a vertical direction. Therefore, a reaction container is constituted by the outer tube 205 and the manifold 209. Here, there is no particular limit to a case where the manifold 209 is installed independently from the outer tube 205, and the manifold 209 may be configured so that the manifold 209 integrated with the outer tube 205 cannot be installed independently.

The boat 217 serving as a substrate-holding unit is, for example, made of a heat-resistant material such as quartz or silicon carbide, and configured to hold a plurality of wafers 200 in multiple stages by concentrically arranging the plurality of wafers 200 in a horizontal posture. At a lower portion of the boat 217, for example, a plurality of heat-insulating plates 216 serving as heat-insulating members made of a heat-resistant material such as quartz or silicon carbide and having a disc shape are horizontally disposed in multiple stages, and thus transfer of heat from the heating device 206 to a side of the manifold 209 is difficult. Instead of the configuration of installing the heat-insulating plate 216, the heat-insulating vat 216 may be installed independently from the boat 217 at the lower end of the boat 217.

Here, as a region configured to hold the plurality of wafers 200 in the boat 217, a region configured to process a substrate is referred to as a substrate processing region 2062, and a region configured to hold the heat-insulating plate 216 is referred to as a heat-insulating region 2061. The substrate processing region 2062 is configured to substantially correspond to a region whose temperature is uniformly controllable by heating from the heating device 206. The heat-insulating region 2061 is configured to have a lower temperature than the region whose temperature is uniformly controlled by heating from the heating device 206, and is configured so that the temperature can drop as the heat-insulating region 2061 goes away from the heating device 206d. That is, the heat-insulating region 2061 is configured to have a lower temperature than that of the substrate processing region 2062 even when the substrate processing region 2062 is heated by the heating device 206.

A nozzle serving as a gas supply unit is installed at an inner part of the processing chamber 201. As the nozzle, a first nozzle 2301, a fifth nozzle 2305, a sixth nozzle 2306, a seventh nozzle 2307, an eighth nozzle 2308 and a ninth nozzle 2309 are configured as a first gas supply unit, a fifth gas supply unit, a sixth gas supply unit, a seventh gas supply unit, an eighth gas supply unit and a ninth gas supply unit, respectively.

The first nozzle 2301 is installed at one end side, that is, a lower end side, of the processing chamber 201. The first nozzle 2301 is installed in a vertical direction with respect to a sidewall of the manifold 209 to have a vertical tube shape. A front end of the first nozzle 2301 is opened, and thus a first gas supply port 931 is formed therein.

The fifth nozzle 2305, the sixth nozzle 2306 and the seventh nozzle 2307 are installed to extend from the one end side, that is, the lower end side, of the processing chamber 201 to the other end side, that is, an upper portion arranged above the first nozzle 2301. The fifth nozzle 2305, the sixth nozzle 2306 and the seventh nozzle 2307 are installed to extend in a vertical direction with respect to the sidewall of the manifold 209 and extend upward in a bent state. Front ends of the fifth nozzle 2305, the sixth nozzle 2306 and the seventh nozzle 2307 are opened, and a fifth gas supply port 935, a sixth gas supply port 936 and a seventh gas supply port 937 are formed at the front ends, respectively.

The eighth nozzle 2308 is installed to extend from the one end side, that is, the lower end side, of the processing chamber 201 to the other end side, that is, an upper portion arranged above the fifth nozzle 2305, the sixth nozzle 2306 and the seventh nozzle 2307. The eighth nozzle 2308 is installed to extend in a vertical direction with respect to the sidewall of the manifold 209, bend upward and extend to the other end side arranged above the fifth nozzle 2305, the sixth nozzle 2306 and the seventh nozzle 2307. A front end of the eighth nozzle 2308 is opened, and thus an eighth gas supply port 938 is formed therein.

The ninth nozzle 2309 is installed to extend from the one end side, that is, the lower end side of the processing chamber 201 to an upper end of the substrate processing region. The ninth nozzle 2309 is installed to extend in a vertical direction with respect to the sidewall of the manifold 209, bend upward and extend to the upper end of the substrate processing region. The ninth nozzle 2309 has a closed upper end, and a plurality of (for example, many) ninth gas supply ports 939 are installed at a sidewall of the ninth nozzle 2309. In this case, the ninth nozzle 2309 is preferably installed at plural places so that a gas can be uniformly supplied to each of the plurality of wafers 200 placed on the boat 217. Also, A ninth nozzle 2309 is preferably installed to be parallel to a gas supply direction through each of the ninth gas supply ports 939 of the ninth nozzles 2309 installed in plural numbers.

Also, the ninth gas supply port 939 may be installed at a gap formed on each wafer 200 in a predetermined height position from a height of an upper surface of the wafer 200, so as to uniformly supply a gas to each of the plurality of wafers 200 placed on the boat 217.

A first gas supply pipe 821 is connected to the first nozzle 2301. A fifth gas supply pipe 825 is connected to the fifth nozzle 2305. A sixth gas supply pipe 826 is connected to the sixth nozzle 2306. A seventh gas supply pipe 827 is connected to the seventh nozzle 2307. An eighth gas supply pipe 828 is connected to the eighth nozzle 2308. A ninth gas supply pipe 829 is connected to the ninth nozzle 2309.

To an upstream side of the first gas supply pipe 821 which is opposite to a contact side of the first nozzle 2301, a mass flow controller (MFC) 2411 serving as a gas flow rate control unit is connected via a valve 5211 serving as a first opening/closing body. To an upstream side of the first gas supply pipe 821 which is opposite to a contact side of the MFC 2411, an ammonia (NH₃) gas supply source 2611 serving as a first gas supply source is connected via a valve 521 serving as the first opening/closing body. The first nozzle 2301, the first gas supply pipe 821, the MFC 2411, the valve 521, the valve 5211 and the ammonia gas supply source 2611 constitute a first gas supply system 811 configured to supply ammonia gas into the processing chamber 201. The first gas supply system 811 is configured to supply the ammonia gas into the processing chamber 201 through the first gas supply port 931 of the first nozzle 2301.

To an upstream side of the fifth gas supply pipe 825 which is opposite to a contact side of the fifth nozzle 2305, a first vaporizer 2415 configured to vaporize a trimethylgallium (Ga(CH₃)₃, hereinafter referred to as TMGa) source which is a gallium-containing source serving as an organic metal source accommodated in a container is connected via a valve 525 serving as a fifth opening/closing body. To an upstream side of the fifth gas supply pipe 825 which is opposite to a contact side of the first vaporizer 2415, an inert gas supply source 2615 serving as a fifth gas supply source is connected via a valve 526 serving as a sixth opening/closing body. Argon (Ar) gas or nitrogen (N₂) gas may be used as the inert gas. The fifth nozzle 2305, the fifth gas supply pipe 825, the first vaporizer 2415, the valve 525, the valve 526 and the inert gas supply source 2615 constitute a fifth gas supply system 815 configured to supply TMGa gas into the processing chamber 201 using the inert gas as a carrier gas. The fifth gas supply system 815 is configured to be able to supply the TMGa gas into the processing chamber 201 through the fifth gas supply port 935 of the fifth nozzle 2305.

To an upstream side of the sixth gas supply pipe 826 which is opposite to a contact side of the sixth nozzle 2306, a second vaporizer 2416 configured to vaporize a trimethylindium ((CH₃)₃In, hereinafter referred to as TMIn) source which is an indium-containing source serving as an organic metal source accommodated in a container is connected via a valve 527 serving as a seventh opening/closing body. To an upstream side of the sixth gas supply pipe 826 which is opposite to a contact side of the second vaporizer 2416, an inert gas supply source 2616 serving as a sixth gas supply source is connected via a valve 528 serving as an eighth opening/closing body. Argon (Ar) gas or nitrogen (N₂) gas may be used as the inert gas.

The sixth nozzle 2306, the sixth gas supply pipe 826, the second vaporizer 2416, the valve 527, the valve 528 and the inert gas supply source 2616 constitute a sixth gas supply system 816 configured to supply TMIn gas into the processing chamber 201 using the inert gas as a carrier gas. The sixth gas supply system 816 is configured to be able to supply the TMIn gas into the processing chamber 201 through the sixth gas supply port 936 of the sixth nozzle 2306.

To an upstream side of the seventh gas supply pipe 827 which is opposite to a contact side of the seventh nozzle 2307, a third vaporizer 2417 configured to vaporize a trimethylaluminum ((CH₃)₃Al, hereinafter referred to as TMAl) source which is an aluminum-containing source serving as an organic metal source accommodated in a container is connected via a valve 529 serving as a ninth opening/closing body. To an upstream side of the seventh gas supply pipe 827 which is opposite to a contact side of the third vaporizer 2417, an inert gas supply source 2617 serving as seventh gas supply source is connected via a valve 5210 serving as a tenth opening/closing body. Argon (Ar) gas or nitrogen (N₂) gas may be used as the inert gas. The seventh nozzle 2307, the seventh gas supply pipe 827, the third vaporizer 2417, the valve 529, the valve 5210 and the inert gas supply source 2617 constitute a seventh gas supply system 817 configured to supply TMAl gas into the processing chamber 201 using the inert gas as a carrier gas. The seventh gas supply system 817 is configured to be able to supply the TMAl gas into the processing chamber 201 through the seventh gas supply port 937 of the seventh nozzle 2307.

To an upstream side of the eighth gas supply pipe 828 which is opposite to a contact side of the eighth nozzle 2308, a fourth vaporizer 2418 configured to vaporize a bis(cyclopentadienyl) magnesium (Mg(C₅H₅)₂, hereinafter referred to as Cp₂Mg) source which is a magnesium-containing source serving as an organic metal source accommodated in a container is connected via a valve 5211 serving as an eleventh opening/closing body. To an upstream side of the eighth gas supply pipe 828 which is opposite to a contact side of the fourth vaporizer 2418, an inert gas supply source 2618 serving as an eighth gas supply source is connected via a valve 5212 serving as a twelfth opening/closing body. Argon (Ar) gas or nitrogen (N₂) gas may be used as the inert gas. The eighth nozzle 2308, the eighth gas supply pipe 828, the fourth vaporizer 2418, the valve 5211, the valve 5212 and the inert gas supply source 2618 constitute an eighth gas supply system 818 configured to supply Cp₂Mg gas into the processing chamber 201 using the inert gas as a carrier gas. The eighth gas supply system 818 is configured to be able to supply the Cp₂Mg gas into the processing chamber 201 through the eighth gas supply port 938 of the eighth nozzle 2308.

To an upstream side of the ninth gas supply pipe 829 which is opposite to a contact side of the ninth nozzle 2309, an MFC 2419 serving as a gas flow rate control unit is connected via a valve 5213 serving as a thirteenth opening/closing body. To an upstream side of the ninth gas supply pipe 829 which is opposite to a contact side of the MFC 2419, a silicon (Si)-containing gas supply source 2619 serving as a ninth gas supply source is connected via a valve 5213 serving as a thirteenth opening/closing body. Also, dichlorosilane (SiH₂Cl₂) gas, monosilane (SiH₄) gas or disilane (Si₂H₆) gas may be used as the silicon-containing gas.

The ninth nozzle 2309, the ninth gas supply pipe 829, the MFC 2419, the valve 5213, the valve 52131 and the silicon-containing gas supply source 2619 constitute a ninth gas supply system 819 configured to supply the silicon-containing gas into the processing chamber 201. The ninth gas supply system 819 is configured to be able to supply the silicon-containing gas into the processing chamber 201 through the ninth gas supply port 939 of the ninth nozzle 2309.

A second gas supply pipe 822 is connected between the first nozzle 2301 and the valve 5211 of the first gas supply pipe 821. To an upstream side of the second gas supply pipe 822 which is opposite to a contact side of the first gas supply pipe 821, an MFC 24121 serving as a gas flow rate control unit is connected via a valve 5221 serving as a second opening/closing body 1. To an upstream side of the second gas supply pipe 822 which is opposite to a contact side of the MFC 24121, a hydrogen (H₂) gas supply source 2612 serving as a second gas supply source is connected via a valve 522 serving as a second opening/closing body.

The second gas supply pipe 822 is connected between the fifth nozzle 2305 and the valve 525 of the fifth gas supply pipe 825. To an upstream side of the second gas supply pipe 822 which is opposite to a contact side of the fifth gas supply pipe 825, an MFC 24122 serving as a gas flow rate control unit is connected via a valve 5222 serving as a second opening/closing body 2. An upstream side of the second gas supply pipe 822 which is opposite to a contact side of the MFC 24122 is connected between the MFC 24121 and the valve 522. That is, the upstream side of the second gas supply pipe 822 which is opposite to the contact side of the MFC 24122 is connected to the hydrogen (H₂) gas supply source 2612 via the valve 522.

The second gas supply pipe 822 is connected between the sixth nozzle 2306 and the valve 529 of the sixth gas supply pipe 826. To an upstream side of the second gas supply pipe 822 which is opposite to a contact side of the sixth gas supply pipe 826, an MFC 24123 serving as a gas flow rate control unit is connected via a valve 5223 serving as a second opening/closing body 3. An upstream side of the second gas supply pipe 822 which is opposite to a contact side of the MFC 24123 is connected between the MFC 24121 and the valve 522. That is, the upstream side of the second gas supply pipe 822 which is opposite to the contact side of the MFC 24123 is connected to the hydrogen (H₂) gas supply source 2612 via the valve 522.

The second gas supply pipe 822 is connected between the seventh nozzle 2307 and the valve 529 of the seventh gas supply pipe 827. To an upstream side of the second gas supply pipe 822 which is opposite to a contact side of the seventh gas supply pipe 827, an MFC 24124 serving as a gas flow rate control unit is connected via a valve 5224 serving as a second opening/closing body 4. An upstream side of the second gas supply pipe 822 which is opposite to a contact side of the MFC 24124 is connected between the MFC 24121 and the valve 522. That is, the upstream side of the second gas supply pipe 822 which is opposite to the contact side of the MFC 24124 is connected to the hydrogen (H₂) gas supply source 2612 via the valve 522.

The second gas supply pipe 822 is connected between the eighth nozzle 2308 and the valve 5211 of the eighth gas supply pipe 828. To an upstream side of the second gas supply pipe 822 which is opposite to a contact side of the eighth gas supply pipe 828, an MFC 24125 serving as a gas flow rate control unit is connected via a valve 5225 serving as a second opening/closing body 5. An upstream side of the second gas supply pipe 822 which is opposite to a contact side of the MFC 24125 is connected between the MFC 24121 and the valve 522. That is, the upstream side of the second gas supply pipe 822 which is opposite to the contact side of the MFC 24125 is connected to the hydrogen (H₂) gas supply source 2612 via the valve 522.

The second gas supply pipe 822 is connected between the ninth nozzle 2309 and the valve 52131 of the ninth gas supply pipe 829. To an upstream side of the second gas supply pipe 822 which is opposite to a contact side of the ninth gas supply pipe 829, an MFC 24126 serving as a gas flow rate control unit is connected via a valve 5226 serving as a second opening/closing body 6. An upstream side of the second gas supply pipe 822 which is opposite to a contact side of the MFC 24126 is connected between the MFC 24121 and the valve 522. That is, the upstream side of the second gas supply pipe 822 which is opposite to the contact side of the MFC 24126 is connected to the hydrogen (H₂) gas supply source 2612 via the valve 522.

The second gas supply pipe 822, the MFC 24121, the MFC 24122, the MFC 24123, the MFC 24124, the MFC 24125, the MFC 24126, the valve 522, the valve 5221, the valve 5222, the valve 5223, the valve 5224, the valve 5225, the valve 5226 and the hydrogen gas supply source 2612 constitute a second gas supply system 812 configured to supply hydrogen gas into the processing chamber 201. That is, the second gas supply system 812 is configured to be able to supply the hydrogen gas into the processing chamber 201 through the first gas supply port 931 of the first nozzle 2301, the fifth gas supply port 935 of the fifth nozzle 2305, the sixth gas supply port 936 of the sixth nozzle 2306, the seventh gas supply port 937 of the seventh nozzle 2307, the eighth gas supply port 938 of the eighth nozzle 2308 and the ninth gas supply port 939 of the ninth nozzle 2309, respectively.

A third gas supply pipe 823 is connected between the first nozzle 2301 and the valve 5211 of the first gas supply pipe 821. To an upstream side of the third gas supply pipe 823 which is opposite to a contact side of the first gas supply pipe 821, an MFC 24131 serving as a gas flow rate control unit is connected via a valve 5231 serving as a third opening/closing body 1. To an upstream side of the third gas supply pipe 823 which is opposite to a contact side of the MFC 24131, an inert gas supply source 2613 serving as a third gas supply source is connected via a valve 523 serving as a third opening/closing body. Argon (Ar) gas or nitrogen (N₂) gas may be used as the inert gas.

The third gas supply pipe 823 is connected between the fifth nozzle 2305 and the valve 525 of the fifth gas supply pipe 825. To an upstream side of the third gas supply pipe 823 which is opposite to a contact side of the fifth gas supply pipe 825, an MFC 24132 serving as a gas flow rate control unit is connected via a valve 5232 serving as a third opening/closing body 2. An upstream side of the third gas supply pipe 823 which is opposite to a contact side of the MFC 24132 is connected between the MFC 24131 and the valve 523. That is, the upstream side of the third gas supply pipe 823 which is opposite to the contact side of the MFC 24132 is connected to the inert gas supply source 2613 via the valve 523.

The third gas supply pipe 823 is connected between the sixth nozzle 2306 and the valve 529 of the sixth gas supply pipe 826. To an upstream side of the third gas supply pipe 823 which is opposite to a contact side of the sixth gas supply pipe 826, an MFC 24133 serving as a gas flow rate control unit is connected via a valve 5233 serving as a third opening/closing body 3. An upstream side of the third gas supply pipe 823 which is opposite to a contact side of the MFC 24133 is connected between the MFC 24131 and the valve 523. That is, the upstream side of the third gas supply pipe 823 which is opposite to the contact side of the MFC 24133 is connected to the inert gas supply source 2613 via the valve 523.

The third gas supply pipe 823 is connected between the seventh nozzle 2307 and the valve 529 of the seventh gas supply pipe 827. To an upstream side of the third gas supply pipe 823 which is opposite to a contact side of the seventh gas supply pipe 827, an MFC 24134 serving as a gas flow rate control unit is connected via a valve 5234 serving as a third opening/closing body 4. An upstream side of the third gas supply pipe 823 which is opposite to a contact side of the MFC 24134 is connected between the MFC 24131 and the valve 523. That is, the upstream side of the third gas supply pipe 823 which is opposite to the contact side of the MFC 24134 is connected to the inert gas supply source 2613 via the valve 523.

The third gas supply pipe 823 is connected between the eighth nozzle 2308 and the valve 5211 of the eighth gas supply pipe 828. To an upstream side of the third gas supply pipe 823 which is opposite to a contact side of the eighth gas supply pipe 828, an MFC 24135 serving as a gas flow rate control unit is connected via a valve 5235 serving as a third opening/closing body 5. An upstream side of the third gas supply pipe 823 which is opposite to a contact side of the MFC 24135 is connected between the MFC 24131 and the valve 523. That is, the upstream side of the third gas supply pipe 823 which is opposite to the contact side of the MFC 24135 is connected to the inert gas supply source 2613 via the valve 523.

The third gas supply pipe 823 is connected between the ninth nozzle 2309 and the valve 52131 of the ninth gas supply pipe 829. To an upstream side of the third gas supply pipe 823 which is opposite to a contact side of the ninth gas supply pipe 829, an MFC 24136 serving as a gas flow rate control unit is connected via a valve 5236 serving as a third opening/closing body 6. An upstream side of the third gas supply pipe 823 which is opposite to a contact side of the MFC 24136 is connected between the MFC 24131 and the valve 523. That is, the upstream side of the third gas supply pipe 823 which is opposite to the contact side of the MFC 24136 is connected to the inert gas supply source 2613 via the valve 523.

The third gas supply pipe 823, the MFC 24131, the MFC 24132, the MFC 24133, the MFC 24134, the MFC 24135, the MFC 24136, the valve 523, the valve 5231, the valve 5232, the valve 5233, the valve 5234, the valve 5235, the valve 5236 and the inert gas supply source 2613 constitute a third gas supply system 813 configured to supply an inert gas into the processing chamber 201. That is, the third gas supply system 813 is configured to be able to supply the inert gas into the processing chamber 201 through the first gas supply port 931 of the first nozzle 2301, the fifth gas supply port 935 of the fifth nozzle 2305, the sixth gas supply port 936 of the sixth nozzle 2306, the seventh gas supply port 937 of the seventh nozzle 2307, the eighth gas supply port 938 of the eighth nozzle 2308, and the ninth gas supply port 939 of the ninth nozzle 2309, respectively.

A fourth gas supply pipe 824 is connected between the first nozzle 2301 and the valve 5211 of the first gas supply pipe 821. To an upstream side of the fourth gas supply pipe 824 which is opposite to a contact side of the first gas supply pipe 821, an MFC 24141 serving as a gas flow rate control unit is connected via a valve 5241 serving as a fourth opening/closing body 1. To an upstream side of the fourth gas supply pipe 824 which is opposite to a contact side of the MFC 24141, a hydrogen chloride (HCl) gas supply source 2614 serving as a fourth gas supply source is connected via a valve 524 serving as a fourth opening/closing body.

The fourth gas supply pipe 824 is connected between the fifth nozzle 2305 and the valve 525 of the fifth gas supply pipe 825. To an upstream side of the fourth gas supply pipe 824 which is opposite to a contact side of the fifth gas supply pipe 825, an MFC 24142 serving as a gas flow rate control unit is connected via a valve 5242 serving as a fourth opening/closing body 2. An upstream side of the fourth gas supply pipe 824 which is opposite to a contact side of the MFC 24142 is connected between the MFC 24141 and the valve 524. That is, the upstream side of the fourth gas supply pipe 824 which is opposite to the contact side of the MFC 24142 is connected to the hydrogen chloride gas supply source 2614 via the valve 524.

The fourth gas supply pipe 824 is connected between the sixth nozzle 2306 and the valve 529 of the sixth gas supply pipe 826. To an upstream side of the fourth gas supply pipe 824 which is opposite to a contact side of the sixth gas supply pipe 826, an MFC 24143 serving as a gas flow rate control unit is connected via a valve 5243 serving as a fourth opening/closing body 3. An upstream side of the fourth gas supply pipe 824 which is opposite to a contact side of the MFC 24143 is connected between the MFC 24141 and the valve 524. That is, the upstream side of the fourth gas supply pipe 824 which is opposite to the contact side of the MFC 24143 is connected to the hydrogen chloride gas supply source 2614 via the valve 524.

The fourth gas supply pipe 824 is connected between the seventh nozzle 2307 and the valve 529 of the seventh gas supply pipe 827. To an upstream side of the fourth gas supply pipe 824 which is opposite to a contact side of the seventh gas supply pipe 827, an MFC 24144 serving as a gas flow rate control unit is connected via a valve 5244 serving as a fourth opening/closing body 4. An upstream side of the fourth gas supply pipe 824 which is opposite to a contact side of the MFC 24144 is connected between the MFC 24141 and the valve 524. That is, the upstream side of the fourth gas supply pipe 824 which is opposite to the contact side of the MFC 24144 is connected to the hydrogen chloride gas supply source 2614 via the valve 524.

The fourth gas supply pipe 824 is connected between the eighth nozzle 2308 and the valve 5211 of the eighth gas supply pipe 828. To an upstream side of the fourth gas supply pipe 824 which is opposite to a contact side of the eighth gas supply pipe 828, an MFC 24145 serving as a gas flow rate control unit is connected via a valve 5245 serving as a fourth opening/closing body 5. An upstream side of the fourth gas supply pipe 824 which is opposite to a contact side of the MFC 24145 is connected between the MFC 24141 and the valve 524. That is, the upstream side of the fourth gas supply pipe 824 which is opposite to the contact side of the MFC 24145 is connected to the hydrogen chloride gas supply source 2614 via the valve 524.

The fourth gas supply pipe 824 is connected between the ninth nozzle 2309 and the valve 52131 of the ninth gas supply pipe 829. To an upstream side of the fourth gas supply pipe 824 which is opposite to a contact side of the ninth gas supply pipe 829, an MFC 24146 serving as a gas flow rate control unit is connected via a valve 5246 serving as a fourth opening/closing body 6. An upstream side of the fourth gas supply pipe 824 which is opposite to a contact side of the MFC 24146 is connected between the MFC 24141 and the valve 524. That is, the upstream side of the fourth gas supply pipe 824 which is opposite to the contact side of the MFC 24146 is connected to the hydrogen chloride gas supply source 2614 via the valve 524.

The fourth gas supply pipe 824, the MFC 24141, the MFC 24142, the MFC 24143, the MFC 24144, the MFC 24145, the MFC 24146, the valve 524, the valve 5241, the valve 5242, the valve 5243, the valve 5244, the valve 5245, the valve 5246 and the hydrogen chloride gas supply source 2614 constitute a fourth gas supply system 814 configured to supply hydrogen chloride gas into the processing chamber 201. That is, the fourth gas supply system 814 is configured to be able to supply the hydrogen chloride gas into the processing chamber 201 through the first gas supply port 931 of the first nozzle 2301, the fifth gas supply port 935 of the fifth nozzle 2305, the sixth gas supply port 936 of the sixth nozzle 2306, the seventh gas supply port 937 of the seventh nozzle 2307, the eighth gas supply port 938 of the eighth nozzle 2308 and the ninth gas supply port 939 of the ninth nozzle 2309, respectively.

A gas flow rate control unit 235 is electrically connected to an MFC such as the MFC 2411, the MFC 24121, the MFC 24122, the MFC 24123, the MFC 24124, the MFC 24125, the MFC 24126, the MFC 24131, the MFC 24132, the MFC 24133, the MFC 24134, the MFC 24135, the MFC 24136, the MFC 24141, the MFC 24142, the MFC 24143, the MFC 24144, the MFC 24145, the MFC 24146, or the MFC 2419, or a valve such as the valve 521, the valve 5211, the valve 522, the valve 5221, the valve 5222, the valve 5223, the valve 5224, the valve 5225, the valve 5226, the valve 523, the valve 5231, the valve 5232, the valve 5233, the valve 5234, the valve 5235, the valve 5236, the valve 524, the valve 5241, the valve 5242, the valve 5243, the valve 5244, the valve 5245, the valve 5246, the valve 525, the valve 526, the valve 527, the valve 528, the valve 529, the valve 5210, the valve 5211, the valve 5212, the valve 5213, or the valve 52131, and a flow rate of a supplied gas is controlled to a desired flow rate at desired times using the gas flow rate control unit 235.

An exhaust pipe 231 configured to exhaust an atmosphere in the processing chamber 201 is installed at the manifold 209. The exhaust pipe 231 is disposed at a lower end portion of a cylindrical space 250 formed by a gap between the inner tube 204 and the outer tube 205, and communicates with the cylindrical space 250. To a downstream side of the exhaust pipe 231 which is opposite to a contact side of the manifold 209, a vacuum exhaust device 246 such as a vacuum pump is connected via a pressure detector 245 serving as a pressure detector and a pressure regulator 242. The vacuum exhaust device 246 is configured to be able to vacuum-exhaust an inner part of the processing chamber 201 so that a pressure in the processing chamber 201 can be adjusted to a predetermined pressure (degree of vacuum). A pressure control unit 236 is electrically connected to the pressure regulator 242 and the pressure detector 245. The pressure control unit 236 is configured to control the processing chamber 201 at desired times, so that a pressure in the processing chamber 201 can reach a desired pressure by means of the pressure regulator 242, based on the pressure detected by the pressure detector 245. Also, the gas exhaust pipe 231 may be, for example, installed at a lower outer wall of the outer tube 205 instead of a sidewall of the manifold 209.

A seal cap 219 is installed below the manifold 209 as a furnace port cover configured to air-tightly close a lower end opening of the manifold 209. The seal cap 219 is, for example, made of a metal such as stainless steel, and is formed in a disc shape. An O-ring 301 serving as a seal member in contact with a lower end of the manifold 209 is installed at an upper surface of the seal cap 219.

A rotary mechanism 254 is installed at the seal cap 219. A rotation shaft 255 of the rotary mechanism 254 is connected to the boat 217 through the seal cap 219, and configured to rotate the boat 217, thereby rotating the wafer 200.

The seal cap 219 is configured to be elevated in a vertical direction by an elevating motor 248 serving as an elevating mechanism installed at an outside of the processing furnace 202, and thus loading and unloading of the boat 217 with respect to the processing chamber 201 are possible.

A driving control unit 237 is electrically connected to the rotary mechanism 254 and the elevating motor 248, and the driving control unit 237 is configured to control at desired times so that the rotary mechanism 254 and the elevating motor 248 can perform a desired operation.

A temperature sensor 263 serving as a temperature-sensing body configured to detect a temperature in the processing chamber 201 is installed in the outer tube 205. A temperature control unit 238 is electrically connected to the heating device 206 and the temperature sensor 263, and is configured to control the processing chamber 201 so that a temperature in the processing chamber 201 can reach a desired temperature distribution at desired times by controlling a transfer of power to the heating device 206, based on temperature information detected by the temperature sensor 263. At least one temperature sensor 263 may be installed, but a plurality of temperature sensors 263 may be installed to improve temperature controllability.

The gas flow rate control unit 235, the pressure control unit 236, the driving control unit 237 and the temperature control unit 238 are electrically connected to a main control unit 239 configured to constitute a manipulation unit or an input/output unit and control the overall substrate processing apparatus 101. The gas flow rate control unit 235, the pressure control unit 236, the driving control unit 237, the temperature control unit 238 and the main control unit 239 constitute a controller 240. As described above, the processing furnace 202 of the substrate processing apparatus 101 in this first embodiment and the surroundings of the processing furnace 202 are configured.

Next, a film-forming operation of forming a film on the wafer 200 using the substrate processing apparatus 101 according to this first embodiment will be described with reference to FIG. 2. Also, in the following description, operations of respective parts constituting the substrate processing apparatus 101 are controlled by the controller 240.

(Boat-Loading Process)

In the substrate processing apparatus 101, a plurality of wafers 200 accommodated in a substrate accommodating unit such as a cassette or a pod are charged into the boat 217 (wafer charging). Then, as show in FIG. 1, the boat 217 configured to hold the plurality of wafers 200 is elevated by a boat elevator 115, and loaded into the processing chamber 201 (boat loading). In this state, the seal cap 219 seals a lower end of the manifold 209 via the O-ring 301.

(Cleaning Process)

After the boat-loading process, nitrogen gas is supplied into the processing chamber 201, and simultaneously vacuum-exhausted from the processing chamber 201. Specifically, as shown in FIG. 1, an inert gas is supplied from the inert gas supply source 2613 as the valve 523 and the valve 5231 are opened, and a flow rate of the inert gas is controlled by the MFC 24131. Then, the inert gas is introduced into the first nozzle 2301 through the third gas supply pipe 823 and the first gas supply pipe 821, and is introduced into the processing chamber 201 through the first gas supply port 931. At the same time, an inner part of the processing chamber 201 is vacuum-exhausted by the vacuum exhaust device 246 so that the inner part of the processing chamber 201 can reach a desired pressure (degree of vacuum). In this case, a pressure in the processing chamber 201 is measured by the pressure detector 245, and the pressure regulator 242 is feedback-controlled, based on the measured pressure.

Meanwhile, the inner part of the processing chamber 201 is heated by the heating device 206 so that the inner part of the processing chamber 201 can reach a desired temperature at which the wafer 200 can be cleaned, for example, a predetermined temperature of 900° C. to 1,100° C. In this case, the transfer of power to the heating device 206 is feedback-controlled, based on the temperature information detected by the temperature sensor 263, so that the inner part of the processing chamber 201 can reach a desired temperature distribution. Then, the wafer 200 rotates as the boat 217 is rotated by the rotary mechanism 254. When the inner part of the processing chamber 201 becomes stable at a predetermined temperature at which the wafer 200 can be cleaned, hydrogen gas serving as a reducing gas is supplied into the processing chamber 201. Specifically, as shown in FIG. 1, the valve 523 and the valve 5231 are closed, and the supply of the inert gas into the processing chamber 201 is stopped. At the same time, the valve 522 and the valve 5221 are opened to supply hydrogen gas from the hydrogen gas supply source 2612, and a flow rate of the hydrogen gas is controlled by the MFC 24121. Thereafter, the hydrogen gas passes through the second gas supply pipe 822 and the first gas supply pipe 821, is introduced into the first nozzle 2301, and is then introduced into the processing chamber 201 through the first gas supply port 931. At the same time, the inner part of the processing chamber 201 is vacuum-exhausted by the vacuum exhaust device 246 so that the inner part of the processing chamber 201 can reach a desired pressure (degree of vacuum). The inner part of the processing chamber 201 is vacuum-exhausted by the vacuum exhaust device 246 so that the inner part of the processing chamber 201 can reach a desired pressure, for example, a predetermined pressure of 66 Pa to 13,330 Pa, and preferably a pressure of 66 Pa to 1333 Pa. In this case, the pressure in the processing chamber 201 is measured by the pressure detector 245, and the pressure regulator 242 is feedback-controlled, based on the measured pressure. A native oxide film or impurities on the wafer 200 are etched by a reduction reaction with the hydrogen gas, thereby performing a cleaning process.

(Cooling Process)

When a pre-set cleaning time lapses, the temperature in the processing chamber 201 is cooled to a treatment temperature for the next process, for example, a predetermined temperature of 500° C. to 700° C. In this case, the transfer of power to the heating device 206 is feedback-controlled, based on the temperature information detected by the temperature sensor 263, so that the inner part of the processing chamber 201 can reach a desired temperature distribution. Hydrogen gas continues to be supplied into the processing chamber 201 through the first gas supply port 931. Also, the inner part of the processing chamber 201 continues to be vacuum-exhausted by the vacuum exhaust device 246 so that the inner part of the processing chamber 201 can reach a desired pressure, for example, a predetermined pressure of 66 Pa to 13,330 Pa, and preferably a pressure of 66 Pa to 1,333 Pa. In this case, the pressure in the processing chamber 201 is measured by the pressure detector 245, and the pressure regulator 242 is feedback-controlled, based on the measured pressure.

(Underlying Buffer Film-Forming Process)

Next, as shown in FIG. 2, a gallium nitride (GaN) buffer layer 2001 is formed as an underlying buffer film on the wafer 200. When a temperature in the processing chamber 201 is stabilized at a predetermined temperature of 500° C. to 600° C., and a pressure in the processing chamber 201 is stabilized at a predetermined pressure of 66 Pa to 13,330 Pa, and preferably a pressure of 66 Pa to 1,333 Pa, ammonia gas as a nitrogen-containing gas, TMGa gas as a gallium-containing gas and hydrogen chloride gas as a chlorine-containing gas are supplied into the processing chamber 201, and a gallium nitride film 2001 is formed on the wafer 200.

Specifically, as shown in FIG. 1, the valve 521 and the valve 5211 are opened, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of the hydrogen chloride gas and the TMGa gas is supplied into the processing chamber 201 through the fifth gas supply port 935 of the fifth nozzle 2305. Thereafter, as heat energy is applied to an inside of the processing chamber 201, the hydrogen chloride gas and the TMGa gas are subjected to chemical reaction, thereby forming gallium chloride (GaCl₃) gas. Then, the gallium chloride gas reacts with the ammonia gas, thereby forming a gallium nitride film on the wafer 200.

Also, when the ammonia gas and the TMGa gas are supplied into the processing chamber 201 at a flow rate ratio of 1:10 to 1:20, the gallium nitride film may be more readily formed to a uniform film thickness on a surface of the wafer 200 held at a lower end of the boat 217, and the gallium nitride film may be readily formed to a uniform film thickness on each of the substrates arranged at the entire substrate processing region. More preferably, when the TMGa gas and the hydrogen chloride gas are supplied into the processing chamber 201 at a flow rate ratio of 1:3 to 1:5, the gallium nitride film may be more readily formed to a uniform film thickness on a surface of the wafer 200 held at a lower end of the boat 217, and the gallium nitride film may be readily formed to a uniform film thickness on each of the substrates arranged at the entire substrate processing region.

This underlying buffer film-forming process has at least one of a plurality of effects, which are described below.

1) Since a nitrogen-containing gas is supplied from one end side of the inside of the processing chamber 201 which is an upstream side of an organic metal gas, the one end side of the inside of the processing chamber 201 is purged by the nitrogen-containing gas, thereby preventing a metal element-containing material from being attached to or deposited on the one end side. That is, the metal element-containing material may be effectively supplied onto the wafer 200 without any unnecessary consumption of the metal element-containing material.

2) Since ammonia gas serving as the nitrogen-containing gas is supplied through the first gas supply port 931 arranged at a lower end side which is one end side of the inside of the processing chamber 201, which is arranged at an upstream side of the fifth gas supply port 935 of the inside of the processing chamber through which the gallium-containing gas is supplied as the organic metal gas, an inner wall of the manifold 209 arranged at a lower end of the inside of the processing chamber 201 is purged by the ammonia gas. Therefore, a gallium-containing product formed by pyrolysis of the hydrogen chloride gas (serving as the chlorine-containing gas) and the TMGa gas (serving as the gallium-containing gas) supplied through the fifth gas supply port 935, or a reaction product of the hydrogen chloride gas and the TMGa gas may be prevented from being attached to or deposited on the inner wall of the manifold 209. Therefore, unnecessary consumption of the TMGa gas may be prevented, and the gallium nitride film may be effectively formed on the wafer 200.

3) Since hydrogen chloride gas serving as the chlorine-containing gas and TMGa gas serving as the gallium-containing gas are supplied through the fifth gas supply port 935 arranged at the heat-insulating region 2061, the hydrogen chloride gas and the TMGa gas are previously heated at the heat-insulating region 2061 prior to reaching the substrate processing region 2062, and the hydrogen chloride gas and the TMGa gas react with each other by heat energy, thereby facilitating generation of gallium chloride (GaCl₃) gas. Therefore, since a gaseous phase of gallium chloride is supplied to the wafer 200 held at the lower end of the inside of the substrate processing region, a gallium nitride film may be readily formed to a uniform film thickness on a surface of the wafer 200 held at the lower end of the inside of the substrate processing region. Also, since unnecessary consumption of the metal-containing material at the one end side of the inside of the processing chamber 201 is prevented, a suitable amount of reactive gas such as gallium chloride gas may be supplied to the wafer 200 held at an upper end of the inside of the substrate processing region. That is, the gallium nitride film may be readily formed to a uniform film thickness on a surface of the wafer 200 held at the upper end of the inside of the substrate processing region. That is, the gallium nitride film may be readily formed to a uniform film thickness on each of the substrates arranged at the entire substrate processing region.

4) Since hydrogen chloride gas serving as the chlorine-containing gas and TMGa gas serving as the gallium-containing gas are supplied into the fifth nozzle 2305, deposition of a Ga ingredient or a gallium-containing material in the fifth nozzle 2305 may be prevented by etching due to a chlorine ingredient of the hydrogen chloride gas even when the Ga ingredient or the gallium-containing material is generated in the fifth nozzle 2305 by chemical reaction such as decomposition of the TMGa gas.

5) Since the fifth nozzle 2305 and the fifth gas supply port 935 are installed at the heat-insulating region 2061, overheating around the fifth nozzle 2305 or the fifth gas supply port 935 is prevented. Therefore, a Ga ingredient generated by pyrolysis of the TMGa gas serving as the gallium-containing gas in the fifth nozzle 2305 or around the fifth gas supply port 935, or a gallium-containing material such as gallium chloride generated by reaction of ammonia gas and gallium chloride gas may be prevented from being attached to or deposited on a vicinity of the fifth gas supply port 935. That is, the gallium nitride film may be effectively formed on the wafer 200, and closing of the inside of the fifth nozzle 2305 and the fifth gas supply port 935 may be prevented at the same time. Preferably, the fifth gas supply port 935 is the heat-insulating region 2061, and may be installed at a higher position than a vertical position of a lower end of a heating element of the heating device 206d. Therefore, the hydrogen chloride gas and the TMGa gas may be further previously heated prior to reaching the substrate processing region 2062, and reaction of the hydrogen chloride gas and the TMGa gas and reaction of the gallium chloride and the ammonia gas may also be facilitated. Also, unnecessary consumption of the metal-containing material at one end of the inside of the processing chamber 201 may be prevented, and the gallium nitride film may be effectively formed on the wafer 200.

Also, although the above-described process describes that the ammonia gas is supplied into the processing chamber 201 through the first gas supply port 931, a mixed gas of ammonia gas, hydrogen gas and nitrogen gas may be supplied instead of the ammonia gas. For example, when the mixed gas of ammonia gas, hydrogen gas and nitrogen gas is supplied instead of the ammonia gas, the supply of the mixed gas may be controlled as follows. The valve 521 and the valve 5211 are opened, a flow rate of ammonia gas supplied from the ammonia gas supply source 2611 is controlled by the MFC 2411, and the ammonia gas is introduced into the first nozzle 2301 through the first gas supply pipe 821, and into the processing chamber 201 through the first gas supply port 931. Also, the valve 522 and the valve 5221 are opened, a flow rate of hydrogen gas supplied from the hydrogen gas supply source 2612 is controlled by the MFC 24121, and the hydrogen gas is introduced into the first nozzle 2301 through the second gas supply pipe 822 and the first gas supply pipe 821, and into the processing chamber 201 through the first gas supply port 931. Also, the valve 523 and the valve 5231 are opened, a flow rate of nitrogen gas serving as the inert gas supplied from the inert gas supply source 2613 is controlled by the MFC 24131, and the nitrogen gas is introduced into the first nozzle 2301 through the third gas supply pipe 823 and the first gas supply pipe 821, and into the processing chamber 201 through the first gas supply port 931. That is, the mixed gas of ammonia gas, hydrogen gas and nitrogen gas may be controlled so that the mixed gas can be introduced into the processing chamber 201 through the first gas supply port 931.

Also, a mixed gas of a nitrogen-containing gas such as nitrogen gas and a hydrogen-containing gas such as hydrogen gas, or other nitrogen- and hydrogen-containing gases may be used instead of the ammonia gas. For example, when the mixed gas of nitrogen gas and hydrogen gas is supplied instead of the ammonia gas without installation of the ammonia gas supply source 2611, the valve 521, the valve 5211 and the MFC 2411, the supply of the mixed gas may be controlled as follows. The valve 522 and the valve 5221 are opened, a flow rate of hydrogen gas supplied from the hydrogen gas supply source 2612 is controlled by the MFC 24121, and the hydrogen gas is introduced into the first nozzle 2301 through the second gas supply pipe 822 and the first gas supply pipe 821, and into the processing chamber 201 through the first gas supply port 931. Also, the valve 523 and the valve 5231 are opened, a flow rate of nitrogen gas serving as an inert gas supplied from the inert gas supply source 2613 is controlled by the MFC 24131, and the nitrogen gas is introduced into the first nozzle 2301 through the third gas supply pipe 823 and the first gas supply pipe 821, and into the processing chamber 201 through the first gas supply port 931. That is, the mixed gas of hydrogen gas and nitrogen gas may be controlled so that the mixed gas can be introduced into the processing chamber 201 through the first gas supply port 931.

Also, a mixed gas of a chlorine-containing gas such as chlorine gas and a hydrogen-containing gas such as hydrogen gas, or other chlorine- and hydrogen-containing gases may be used instead of the hydrogen chloride gas. For example, when a chlorine gas supply source is installed instead of the hydrogen chloride gas supply source 2614, the supply of the mixed gas may be controlled, as follows.

The valve 522 and the valve 5222 are opened, a flow rate of hydrogen gas supplied from the hydrogen gas supply source 2612 is controlled by the MFC 24122, and the hydrogen gas is introduced into the fifth nozzle 2305 through the second gas supply pipe 822 and the fifth gas supply pipe 825, and into the processing chamber 201 through the fifth gas supply port 935. Also, the valve 524 and the valve 5242 are opened, a flow rate of chlorine gas supplied from the chlorine gas supply source is controlled by the MFC 24142, and the chlorine gas is introduced into the fifth nozzle 2305 through the fourth gas supply pipe 824 and the fifth gas supply pipe 825, and into the processing chamber 201 through the fifth gas supply port 935. That is, a mixed gas of hydrogen gas, chlorine gas and TMGa gas may be controlled so that the mixed gas can be introduced into the processing chamber 201 through the fifth gas supply port 935.

Also, a mixed gas of TMGa gas, hydrogen chloride gas, hydrogen gas and nitrogen gas may be supplied instead of the supply of the mixed gas of TMGa gas and hydrogen chloride gas into the processing chamber 201 through the fifth gas supply port 935. For example, the supply of the mixed gas may be controlled as follows. The valve 524 and the valve 5244 are opened, hydrogen chloride gas is supplied from the hydrogen chloride gas supply source 2614, a flow rate of the hydrogen chloride gas is controlled by the MFC 24144, and the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, a TMGa source is vaporized by the first vaporizer 2415, introduced into the fifth nozzle 2305 through the fifth gas supply pipe 825, and introduced into the processing chamber 201 through the fifth gas supply port 935. The valve 522 and the valve 5222 are opened, a flow rate of hydrogen gas supplied from the hydrogen gas supply source 2612 is controlled by the MFC 24122, and the hydrogen gas is introduced into the fifth nozzle 2305 through the second gas supply pipe 822 and the fifth gas supply pipe 825, and into the processing chamber 201 through the fifth gas supply port 935. Also, the valve 523 and the valve 5232 are opened, a flow rate of nitrogen gas serving as the inert gas supplied from the inert gas supply source 2613 is controlled by the MFC 24132, and the nitrogen gas is introduced into the fifth nozzle 2305 through the third gas supply pipe 823 and the fifth gas supply pipe 825, and into the processing chamber 201 through the fifth gas supply port 935. That is, a mixed gas of hydrogen chloride gas, hydrogen gas, nitrogen gas and TMGa gas may be controlled so that the mixed gas can be introduced into the processing chamber 201 through the fifth gas supply port 935.

Also, a mixed gas of TMGa gas, hydrogen gas and chlorine gas, or a mixed gas of TMGa gas, hydrogen gas, chlorine gas and nitrogen gas may be supplied instead of the supply of the mixed gas of TMGa gas and hydrogen chloride gas into the processing chamber 201 through the fifth gas supply port 935.

Also, a gallium-containing gas such as gallium chloride (GaCl₃) gas may be used instead of the TMGa gas. For example, when a gallium chloride gas supply source is installed instead of the inert gas supply source 2615, and an MFC is installed instead of the first vaporizer 2415, the gallium chloride gas, instead of the TMGa gas, may be supplied into the processing chamber 201 through the fifth gas supply port 935. Even when the gallium chloride gas is used, a mixed gas of gallium chloride gas and hydrogen chloride gas may be supplied into the processing chamber 201 through the fifth gas supply port 935, or a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied into the processing chamber 201 through the fifth gas supply port 935.

Also, this underlying buffer film-forming process may be performed directly after the boat-loading process without performing the cleaning process or the cooling process.

(Heating Process)

After the underlying buffer film-forming process, a temperature in the processing chamber 201 is heated to a treatment temperature for the next process, for example, a predetermined temperature of 900° C. to 1,100° C. In this case, a transfer of power to the heating device 206 is feedback-controlled, based on the temperature information detected by the temperature sensor 263, so that an inside of the processing chamber 201 can reach a desired temperature distribution Ammonia gas continues to be supplied into the processing chamber 201 through the first gas supply port 931. Also, the inside of the processing chamber 201 continues to be vacuum-exhausted by the vacuum exhaust device 246 so that the inside of the processing chamber 201 can reach a desired pressure, for example, a predetermined pressure 66 Pa to 13,330 Pa, and preferably a pressure of 66 Pa to 1,333 Pa. In this case, a pressure in the processing chamber 201 is measured by the pressure detector 245, and the pressure regulator 242 is feedback-controlled, based on the measured pressure. In this case, ammonia gas and nitrogen gas may be supplied instead of the supply of the ammonia gas into the processing chamber 201.

(Gallium Nitride Epitaxial Film-Forming Process)

Next, as shown in FIG. 2, a gallium nitride epitaxial layer 2002 serving as a gallium nitride epitaxial (GaN) film is formed on an underlying gallium nitride film 2001. When A temperature in the processing chamber 201 becomes stable at a predetermined temperature of 900° C. to 1,100° C., and a pressure in the processing chamber 201 becomes stable at a predetermined pressure of 66 Pa to 13,330 Pa, and preferably a pressure of 66 Pa to 1,333 Pa, ammonia gas serving as the nitrogen-containing gas, TMGa gas serving as the gallium-containing gas and hydrogen chloride gas serving as the chlorine-containing gas are supplied into the processing chamber 201, thereby forming a gallium nitride epitaxial film 2002 on an underlying gallium nitride film arranged on the wafer 200. Specifically, as shown in FIG. 1, the valve 521 and the valve 5211 are opened, ammonia gas is supplied from the ammonia gas supply source 2611, and a flow rate of the ammonia gas is controlled by the MFC 2411.

Then, the ammonia gas is introduced into the first nozzle 2301 through the first gas supply pipe 821, and into the processing chamber 201 through the first gas supply port 931.

Also, the valve 524 and the valve 5244 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615, and a TMGa source is vaporized by the first vaporizer 2415. Thereafter, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935 of the fifth nozzle 2305. Then, as heat energy is applied to an inside of the processing chamber 201, the hydrogen chloride gas and the TMGa gas are subjected to a chemical reaction, thereby forming gallium chloride (GaCl₃) gas. Then, the gallium chloride gas reacts with the ammonia gas, thereby forming a gallium nitride epitaxial film on the underlying gallium nitride film arranged on the wafer 200.

Also, when the ammonia gas and the TMGa gas are supplied into the processing chamber 201 at a flow rate ratio of 1:10 to 1:50, a gallium nitride epitaxial film may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, a gallium nitride epitaxial film may be more readily formed to a uniform film thickness on a surface of the wafer 200 held at a lower end of the boat 217, and a gallium nitride film may be readily formed to a uniform film thickness on each of the substrates arranged at the entire substrate processing region.

This gallium nitride film-forming process has the same effect as at least one of the plurality of effects described in the description of the underlying buffer film-forming process, and also has at least one of a plurality of effects to be described later. After an underlying buffer film is formed on a substrate, a gallium nitride epitaxial film may be formed on the underlying buffer film in the same processing chamber without unloading the substrate from the processing chamber, and thus a high-quality stacked layer may be formed without interposing the impurities or native oxide film between the underlying buffer film and the gallium nitride film, thereby improving throughput.

Also in this process, like the above-described underlying buffer film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied.

(N-Type Semiconductor Film-Forming Process)

Next, as shown in FIG. 2, a silicon-doped gallium (Si-Doped-GaN) layer 2003 serving as an N-type semiconductor film is formed on the gallium nitride epitaxial film 2002. When a temperature in the processing chamber 201 becomes stable at a predetermined temperature of 900° C. to 1100° C., and a pressure in the processing chamber 201 becomes stable at a predetermined pressure of 66 Pa to 13,330 Pa, and preferably a pressure of 66 Pa to 1333 Pa, ammonia gas serving as the nitrogen-containing gas, TMGa gas serving as the gallium-containing gas, hydrogen chloride gas serving as the chlorine-containing gas, and a silicon-containing gas serving as a dopant gas, preferably, for example, dichlorosilane gas serving as a silicon- and chlorine-containing gas, is supplied into the processing chamber 201, and a silicon-doped gallium nitride film serving as a silicon-containing gallium nitride film is formed on the wafer 200.

Specifically, as shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, and a TMGa source is vaporized by the first vaporizer 2415. Thereafter, the TMGa gas is introduced into the fifth nozzle 2305 through the fifth gas supply pipe 825, and into the processing chamber 201 through the fifth gas supply port 935. That is, the mixed gas of hydrogen chloride gas and TMGa gas is supplied into the processing chamber 201 through the fifth gas supply port 935.

Also, the valve 5213 and the valve 52131 are opened, dichlorosilane gas serving as the dopant gas is supplied from a dichlorosilane gas supply source 2619, and a flow rate of the dichlorosilane gas is controlled by the MFC 2419. Then, the dichlorosilane gas is introduced into the ninth nozzle 2309 through the ninth gas supply pipe 829, and into the processing chamber 201 through the ninth gas supply port 939.

The hydrogen chloride gas and the TMGa gas are subjected to a chemical reaction such as decomposition in the processing chamber 201, thereby forming gallium chloride (GaCl₃) gas. Then, a silicon-doped gallium nitride film 2003 embedded with silicon and serving as the gallium nitride film is formed on the gallium nitride epitaxial film formed on the wafer 200 by reaction of the gallium chloride gas, the ammonia gas and the dichlorosilane gas.

Also, when the ammonia gas and the TMGa gas are supplied into the processing chamber 201 at a flow rate ratio of 1:10 to 1:50, a silicon-doped gallium nitride film may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, a silicon-doped gallium nitride film may be more readily formed to a uniform film thickness on a surface of the wafer 200 held at a lower end of the boat 217, and a silicon-doped gallium nitride film may be readily formed to a uniform film thickness on each of the substrates arranged at the entire substrate processing region.

Also, when this process is performed under the same conditions as the gallium nitride epitaxial film-forming process, including the temperature and pressure in the processing chamber 201, a smooth transfer from the gallium nitride epitaxial film-forming process to the N-type semiconductor film-forming process may be performed, thereby improving throughput.

This process has the same effect as at least one of the plurality of effects described in the description of the underlying buffer film-forming process, and also has at least one of a plurality of effects, which are described below.

1) Since silicon- and chlorine-containing gases, or a mixed gas of a silicon-containing gas and a chlorine-containing gas, are supplied from a circumferential side portion of the wafer 200, these gases are easily introduced between the wafers 200, and these gases are also easily introduced into a central portion of the wafer 200, as well as a circumferential portion of the wafer 200. Therefore, since silicon atoms are easily injected to a film arranged at the central portion of the wafer 200, the silicon atoms in the gallium nitride film may be easily uniformly distributed in a surface of the wafer 200.

2) Since silicon- and chlorine-containing gases or a mixed gas of a silicon-containing gas and a chlorine-containing gas are supplied from a circumferential side portion of the wafer 200 in the substrate processing region 2062 through the ninth gas supply port 939 of the ninth nozzle 2309, the silicon- and chlorine-containing gases or the mixed gas of a silicon-containing gas and a chlorine-containing gas are easily introduced between the wafers 200, and the silicon- and chlorine-containing gases or the mixed gas of a silicon-containing gas and a chlorine-containing gas are easily introduced into a central portion of the wafer 200, as well as a circumferential portion of the wafer 200. Therefore, since silicon atoms are easily injected to a film arranged at the central portion of the wafer 200, the silicon atoms in the gallium nitride film may be easily uniformly distributed in a surface of the wafer 200. In particular, since a dopant gas is supplied in a smaller amount than the TMGa gas serving as a film-forming gas, an amount of a dopant in a film is easily changed by vertical disposition of a plurality of wafers 200 arranged at the substrate processing region 2062 when the dopant gas is supplied from the heat-insulating region 2061, but when the dopant gas is supplied through the ninth gas supply port 939 of the ninth nozzle 2309 arranged at the substrate processing region 2062, an amount of a dopant in a film is uniformly distributed regardless of vertical disposition of the plurality of wafers 200 arranged at the substrate processing region 2062.

3) Since the silicon- and chlorine-containing gases or the mixed gas of a silicon-containing gas and a chlorine-containing gas are supplied into the ninth nozzle 2309, the silicon- and chlorine-containing gases or the mixed gas of a silicon-containing gas and a chlorine-containing gas are subjected to a chemical reaction such as decomposition. Even when a silicon ingredient or a silicon-containing material is generated in the ninth nozzle 2309, the silicon ingredient or the silicon-containing material may be prevented from being deposited in the ninth nozzle 2309 by etching due to a chlorine ingredient.

4) After formation of the gallium nitride epitaxial film on the substrate, a silicon-doped gallium nitride film may be formed on a gallium nitride film in the same processing chamber without unloading the substrate from the processing chamber, and thus a high-quality stacked layer may be formed without interposing the impurities or native oxide film between the gallium nitride epitaxial film and the silicon-doped gallium nitride film, thereby improving throughput.

Also in this process, a mixed gas of a silicon-containing gas and a chlorine-containing gas such as monosilane (SiH₄) gas, trichlorosilane (SiHCl₃) gas or silane tetrahydride (SiCl₄) gas, or silicon- and chlorine-containing gases may be used instead of the dichlorosilane gas. For example, when the dichlorosilane gas supply source 2619 is exchanged with a monosilane gas supply source, the supply of the mixed gas may be controlled as follows. The valve 524 and the valve 5246 are opened, a flow rate of hydrogen chloride gas supplied from the hydrogen chloride gas supply source 2614 is controlled by the MFC 24146, and the hydrogen chloride gas is introduced into the ninth nozzle 2309 through the fourth gas supply pipe 824 and the ninth gas supply pipe 829, and into the processing chamber 201 through the ninth gas supply port 939. Also, the valve 5213 and the valve 52131 are opened, a flow rate of monosilane gas supplied from the monosilane gas supply source is controlled by the MFC 2419, and the monosilane gas is introduced into the ninth nozzle 2309 through the ninth gas supply pipe 829, and into the processing chamber 201 through the ninth gas supply port 939. That is, a mixed gas of hydrogen chloride gas and monosilane gas may be controlled so that the mixed gas can be supplied into the processing chamber 201 through the ninth gas supply port 939.

Also in this process, like the above-described underlying buffer film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas gallium chloride gas, hydrogen gas and chlorine gas, or a mixed gas of gallium chloride gas, hydrogen gas, chlorine gas and nitrogen gas may be supplied.

(Cooling Process)

When a preset N-type semiconductor film-forming time lapses, the supply of ammonia gas, TMGa gas, hydrogen chloride gas and dichlorosilane gas into the processing chamber 201 is stopped, and a temperature in the processing chamber 201 is cooled to a treatment temperature for the next process, for example, a predetermined temperature of 700° C. to 800° C. In this case, a transfer of power to the heating device 206 is feedback-controlled, based on the temperature information detected by the temperature sensor 263, so that an inside of the processing chamber 201 can reach a desired temperature distribution. Nitrogen gas is supplied into the processing chamber 201 through the fifth gas supply port 935. Also, the inside of the processing chamber 201 is vacuum-exhausted by the vacuum exhaust device 246 so that the inside of the processing chamber 201 can reach a desired pressure, for example, a predetermined pressure of 66 Pa to 13,330 Pa, and preferably a pressure of 66 Pa to 1,333 Pa. In this case, a pressure in the processing chamber 201 is measured by the pressure detector 245, and the pressure regulator 242 is feedback-controlled, based on the measured pressure.

(Light-Emitting Film-Forming Process)

Next, as shown in FIG. 2, a stacked layer of a gallium nitride layer 2004 and a indium gallium nitride layer 2005, which serves as a light-emitting film, is formed on the silicon-doped gallium nitride film 2003. When a temperature in the processing chamber 201 becomes stable at a predetermined temperature of 700° C. to 800° C., and a pressure in the processing chamber 201 becomes stable at a predetermined pressure of 66 Pa to 13,330 Pa, and preferably a pressure of 66 Pa to 1333 Pa, ammonia gas serving as the nitrogen-containing gas, TMGa gas serving as the gallium-containing gas, and hydrogen chloride gas serving as the chlorine-containing gas are supplied into the processing chamber 201 while maintaining a stable state of a corresponding pressure, thereby forming the gallium nitride film 2004 in an amorphous state on the wafer 200. Then, ammonia gas serving as the nitrogen-containing gas, TMGa gas serving as the gallium-containing gas, hydrogen chloride gas serving as the chlorine-containing gas, and TMIn gas serving as the indium-containing gas are supplied to form an indium gallium nitride film 2005. Preferably, the gallium nitride film 2004 and the indium gallium nitride film 2005 are alternately stacked on each other with the gallium nitride film 2004 being a lowest layer.

First, a process of forming the amorphous gallium nitride film 2004 on the wafer 200 will be described.

As shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935.

The hydrogen chloride gas and the TMGa gas are subjected to a chemical reaction such as decomposition in the processing chamber 201, thereby forming gallium chloride (GaCl₃) gas. Then, an amorphous gallium nitride film is formed on the wafer 200 by reaction of the gallium chloride gas and the ammonia gas.

Next, a process of forming the indium gallium nitride film 2005 on the wafer 200 will be described.

As shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935.

Also, the valve 524 and the valve 5243 are opened, hydrogen chloride gas is supplied from the hydrogen chloride gas supply source 2614, and a flow rate of the hydrogen chloride gas is controlled by the MFC 24143. Then, the hydrogen chloride gas is introduced into the sixth nozzle 2306 through the fourth gas supply pipe 824 and the sixth gas supply pipe 826, and into the processing chamber 201 through the sixth gas supply port 936. Also, the valve 528 and the valve 527 are opened, an inert gas is supplied from the inert gas supply source 2616 to the second vaporizer 2416, and a TMIn source is vaporized by the second vaporizer 2416. Then, the TMIn gas is introduced into the sixth nozzle 2306 through the sixth gas supply pipe 826, and into the processing chamber 201 through the sixth gas supply port 936. That is, a mixed gas of hydrogen chloride gas and TMIn gas is supplied into the processing chamber 201 through the sixth gas supply port 936.

The hydrogen chloride gas and the TMGa gas are subjected to a chemical reaction such as decomposition in the processing chamber 201, and gallium chloride (GaCl₃) gas is formed. Then, the indium gallium nitride film 2005 is formed on the wafer 200 by reaction of the gallium chloride gas, the ammonia gas and the TMIn gas.

The above-described processes of forming the gallium nitride film 2004 and the indium gallium nitride film 2005 are performed several times (the process of forming the gallium nitride film 2004 is performed four times, and the process of forming the indium gallium nitride film 2005 is performed three times in the embodiment shown in FIG. 2), and a stacked layer of the gallium nitride film 2004 and the indium gallium nitride film 2005 is formed.

Also, when the ammonia gas and the TMGa gas are supplied into the processing chamber 201 at a flow rate ratio of 1:10 to 1:50, a stacked layer of the gallium nitride film 2004 and the indium gallium nitride film 2005 may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, a stacked layer of the gallium nitride film 2004 and the indium gallium nitride film 2005 may be more easily formed to a uniform film thickness on a surface of the wafer 200 held at a lower end of the boat 217, and a stacked layer of the gallium nitride film 2004 and the indium gallium nitride film 2005 may be easily formed to a uniform film thickness on each of the substrates arranged at the entire substrate processing region.

This process has the same effect as at least one of the plurality of effects described in the description of the underlying buffer film-forming process and the gallium nitride epitaxial film-forming process, and also has at least one of a plurality of effects, which are described below.

1) Since ammonia gas serving as the nitrogen-containing gas is supplied from one end side, that is, a lower end side, of the inside of the processing chamber 201 through the first gas supply port 931 of the first nozzle 2301, rather than the fifth gas supply port 935, an inner wall of the manifold 209 arranged at the lower end of the inside of the processing chamber 201 is purged by the ammonia gas. Therefore, an indium-containing product, which is generated by pyrolysis of TMIn gas serving as the indium-containing gas supplied through the sixth gas supply port 936, may be prevented from being attached to or deposited on the inner wall of the manifold 209. Therefore, unnecessary consumption of the TMIn gas may be prevented, and the indium gallium nitride film may be effectively formed on the wafer 200.

2) Since a chlorine-containing gas is supplied into the sixth nozzle 2306, deposition of an indium ingredient or an indium-containing material in the sixth nozzle 2306 may be prevented by etching due to a chlorine ingredient even when the indium ingredient or the indium-containing material is generated in the sixth nozzle 2306 by chemical reaction such as decomposition of the indium-containing gas.

3) Since the TMIn gas serving as the indium-containing gas is supplied through the sixth gas supply port 936 arranged at the heat-insulating region 2061, the TMIn gas is previously heated prior to reaching the substrate processing region 2062, and when the TMIn gas reacts by heat energy, a reaction such as decomposition of an indium ingredient may be facilitated. Therefore, an indium gallium nitride film having a uniform film thickness may be formed on a surface of the wafer 200 held at a lower end of the boat 217. Accordingly, an indium gallium nitride film having a uniform film thickness may be easily formed on each of the substrates arranged at the entire substrate processing region.

4) Since the hydrogen chloride gas serving as the chlorine-containing gas and the TMGa gas serving as the gallium-containing gas are supplied into the fifth nozzle 2305, deposition of a gallium ingredient or a gallium-containing material in the fifth nozzle 2305 may be prevented by etching due to a chlorine ingredient of the hydrogen chloride gas even when the gallium ingredient or the gallium-containing material is generated in the fifth nozzle 2305 by a chemical reaction such as decomposition of the TMGa gas.

5) Since the fifth nozzle 2305 and the fifth gas supply port 935 are installed at the heat-insulating region 2061, overheating around the fifth nozzle 2305 or the fifth gas supply port 935 is prevented. Therefore, a gallium ingredient generated by pyrolysis of the TMGa gas serving as the gallium-containing gas in the fifth nozzle 2305 or around the fifth gas supply port 935, or a gallium-containing material such as gallium chloride generated by reaction of ammonia gas and gallium chloride gas may be prevented from being attached to or deposited on a vicinity of the fifth gas supply port 935. That is, the gallium nitride film may be effectively formed on the wafer 200, and closing of the inside of the fifth nozzle 2305 and the fifth gas supply port 935 may be prevented at the same time.

Preferably, the fifth gas supply port 935 becoming an upper end of the fifth nozzle 2305 is the heat-insulating region 2061, and may be installed at a higher position than a vertical position of a lower end of a heating element of the heating device 206d. Therefore, the hydrogen chloride gas and the TMGa gas may be further previously heated prior to reaching the substrate processing region 2062, and reaction of the hydrogen chloride gas and the TMGa gas and reaction of the gallium chloride and the ammonia gas may also be facilitated. Also, the gallium nitride film may be more effectively formed on the wafer 200, and closing of an inside of the fifth nozzle 2305 and the fifth gas supply port 935 may be prevented.

6) When the processes of forming the gallium nitride film 2004 and the indium gallium nitride film 2005 are performed under the same conditions including the temperature and pressure in the processing chamber 201, a smooth transfer from the process of forming the gallium nitride film 2004 to the process of forming the indium gallium nitride film 2005 may be performed, thereby improving throughput.

Also in this process, as a gas which is mixed with TMIn gas in the sixth gas nozzle 2306, chlorine gas and hydrogen gas may be used instead of the hydrogen chloride gas. For example, when the hydrogen chloride gas supply source 2614 is exchanged with a chlorine gas supply source, the supply of the chlorine gas and hydrogen gas may be controlled as follows. The valve 524 and the valve 5243 are opened, a flow rate of chlorine gas supplied from the chlorine gas supply source is controlled by the MFC 24143, and the chlorine gas is introduced into the sixth nozzle 2306 through the fourth gas supply pipe 824 and the sixth gas supply pipe 826, and into the processing chamber 201 through the sixth gas supply port 936. Also, the valve 522 and the valve 5223 are opened, a flow rate of hydrogen gas supplied from the hydrogen gas supply source 2412 is controlled by the MFC 24123, and the hydrogen gas is introduced into the sixth nozzle 2306 through the second gas supply pipe 822 and the sixth gas supply pipe 826, and into the processing chamber 201 through the sixth gas supply port 936. Also, the valve 528 and the valve 527 are opened, an inert gas supplied from the inert gas supply source 2416 is supplied to the second vaporizer 2416, and a TMIn source is vaporized by the second vaporizer 2416, introduced into the sixth nozzle 2306 through the sixth gas supply pipe 826, and introduced into the processing chamber 201 through the sixth gas supply port 936. That is, a mixed gas of chlorine gas, hydrogen gas and TMIn gas may be controlled so that the mixed gas can be supplied into the processing chamber 201 through the sixth gas supply port 936.

Also in this process, like the above-described underlying buffer film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied.

(Heating Process)

When a preset treatment time lapses, a temperature in the processing chamber 201 is increased to a treatment temperature for the next process, for example a predetermined temperature of 900° C. to 1100° C. In this case, a transfer of power to the heating device 206 is feedback-controlled, based on the temperature information detected by the temperature sensor 263, so that the inside of the processing chamber 201 can reach a desired temperature distribution Ammonia gas continues to be supplied into the processing chamber 201 through the first gas supply port 931. Also, the inside of the processing chamber 201 continues to be vacuum-exhausted by the vacuum exhaust device 246 so that the inside of the processing chamber 201 can reach a desired pressure, for example, a predetermined pressure of 66 Pa to 13,330 Pa, and preferably a pressure of 66 Pa to 1,333 Pa. In this case, a pressure in the processing chamber 201 is measured by the pressure detector 245, and the pressure regulator 242 is feedback-controlled, based on the measured pressure. Also, ammonia gas and nitrogen gas may be supplied instead of the supply of ammonia gas into the processing chamber 201.

(Barrier Film-Forming Process)

Next, as shown in FIG. 2, an aluminum gallium nitride (AlGaN) layer 2006 serving as a barrier film is formed on a highest layer of the gallium nitride layers 2004. When a temperature in the processing chamber 201 becomes stable at a predetermined temperature of 900° C. to 1,100° C., and a pressure in the processing chamber 201 becomes stable at a predetermined pressure of 66 Pa to 13,330 Pa, and preferably a pressure of 66 Pa to 1,333 Pa, ammonia gas serving as the nitrogen-containing gas, TMGa gas serving as the gallium-containing gas, hydrogen chloride gas serving as the chlorine-containing gas, and trimethylaluminum (TMAl) gas serving as the aluminum (Al)-containing gas are supplied into the processing chamber 201 while maintaining a stable state of the pressure, thereby forming the aluminum gallium nitride film 2006 on the wafer 200.

Specifically, as shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935.

Also, the valve 524 and the valve 5244 are opened, hydrogen chloride gas is supplied from the hydrogen chloride gas supply source 2614, and a flow rate of the hydrogen chloride gas is controlled by the MFC 24144. Then, the hydrogen chloride gas is introduced into the seventh nozzle 2307 through the fourth gas supply pipe 824 and the seventh gas supply pipe 827, and into the processing chamber 201 through the seventh gas supply port 937. Also, the valve 5210 and the valve 529 are opened, and inert gas is supplied from the inert gas supply source 2617 to the third vaporizer 2417, and a TMAl source is vaporized by the third vaporizer 2417. Then, the TMAl gas is introduced into the seventh nozzle 2307 through the seventh gas supply pipe 827, and into the processing chamber 201 through the seventh gas supply port 937. That is, a mixed gas of hydrogen chloride gas and TMAl gas is supplied into the processing chamber 201 through the seventh gas supply port 937.

The hydrogen chloride gas and the TMGa gas are subjected to a chemical reaction such as decomposition in the processing chamber 201, and gallium chloride (GaCl₃) gas is formed. Then, the aluminum gallium nitride film 2006 is formed on a highest layer of the gallium nitride layers 2004 arranged on the wafer 200 by reaction of the gallium chloride gas, the ammonia gas and the TMAl gas.

Also, when the ammonia gas and the TMGa gas are supplied into the processing chamber 201 at a flow rate ratio of 1:10 to 1:50, an aluminum gallium nitride film may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, an aluminum gallium nitride film may be more readily formed to a uniform film thickness on a surface of the wafer 200 held at a lower end of the boat 217, and an aluminum gallium nitride film may be readily formed to a uniform film thickness on each of the substrates arranged at the entire substrate processing region.

This process has the same effect as at least one of the plurality of effects described in the description of the underlying buffer film-forming process, and also has at least one of a plurality of effects, which are described below.

1) Since the chlorine-containing gas is supplied into the seventh nozzle 2307, deposition of an aluminum ingredient or an aluminum-containing material in the seventh nozzle 2307 may be prevented by etching due to a chlorine ingredient even when the aluminum-containing gas is subjected to a chemical reaction such as decomposition, and the aluminum ingredient or the aluminum-containing material is generated in the seventh nozzle 2307. Preferably, the fifth gas supply port 935 becoming an upper end of the fifth nozzle 2305 is the heat-insulating region 2061, and may be installed at a higher position than a vertical position of a lower end of a heating element of the heating device 206d. Therefore, the hydrogen chloride gas and the TMGa gas may be further previously heated prior to reaching the substrate processing region 2062, and a reaction of the hydrogen chloride gas and the TMGa gas and a reaction of the gallium chloride and the ammonia gas may also be facilitated. Also, a gallium nitride film may be more effectively formed on the wafer 200, and closing of an inside of the fifth nozzle 2305 and the fifth gas supply port 935 may be prevented.

Also in this process, as a gas which is mixed with TMIn gas in the seventh gas nozzle 2307, chlorine gas and hydrogen gas may be used instead of the hydrogen chloride gas. For example, when the hydrogen chloride gas supply source 2614 is exchanged with a chlorine gas supply source, the supply of the chlorine gas and hydrogen gas may be controlled, as follows. The valve 524 and the valve 5244 are opened, a flow rate of chlorine gas supplied from the chlorine gas supply source is controlled by the MFC 24144, and the chlorine gas is introduced into the seventh nozzle 2307 through the fourth gas supply pipe 824 and the seventh gas supply pipe 827, and into the processing chamber 201 through the seventh gas supply port 937. Also, the valve 522 and the valve 5224 are opened, a flow rate of hydrogen gas supplied from the hydrogen gas supply source 2412 is controlled by the MFC 24124, and the hydrogen gas is introduced into the seventh nozzle 2307 through the second gas supply pipe 822 and the seventh gas supply pipe 827, and into the processing chamber 201 through the seventh gas supply port 937. Also, the valve 5210 and the valve 529 are opened, an inert gas supplied from the inert gas supply source 2417 is supplied to the third vaporizer 2417, and a TMAl source is vaporized by the third vaporizer 2417, introduced into the seventh nozzle 2307 through the seventh gas supply pipe 827, and introduced into the processing chamber 201 through the seventh gas supply port 937. That is, a mixed gas of chlorine gas, hydrogen gas and TMAl gas may be controlled so that the mixed gas can be supplied into the processing chamber 201 through the seventh gas supply port 937.

Also in this process, like the above-described underlying buffer film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied.

Also in this process, a hydrogen gas supply source may be provided instead of the above-described inert gas supply source 2617. That is, hydrogen gas may be used as a gas for vaporizing the TMAl source.

(P-Type Semiconductor Film-Forming Process)

Next, as shown in FIG. 2, a magnesium-doped aluminum gallium nitride (Mg-Doped AlGaN) layer 2007, which is a P-type-doped aluminum gallium nitride layer, serving as a P-type semiconductor film is formed on the aluminum gallium nitride layer 2006. When a temperature in the processing chamber 201 becomes stable at a predetermined temperature of 900° C. to 1,100° C., and a pressure in the processing chamber 201 becomes stable at a predetermined pressure of 66 Pa to 13,330 Pa, and preferably a pressure of 66 Pa of 1,333 Pa, ammonia gas serving as the nitrogen-containing gas, TMGa gas serving as the gallium-containing gas, hydrogen chloride gas serving as the chlorine-containing gas, trimethylaluminum (TMAl) gas serving as the aluminum (Al)-containing gas, and bis(cyclopentadienyl) magnesium (Cp₂Mg) gas, which is a magnesium-containing gas, serving as a magnesium (Mg) dopant gas are supplied into the processing chamber 201 while maintaining stable states of the temperature and the corresponding pressure, and a magnesium-doped aluminum gallium nitride film 2007 serving as a magnesium- and aluminum-containing gallium nitride film is formed on the wafer 200.

Specifically, as shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935.

Also, the valve 524 and the valve 5244 are opened, hydrogen chloride gas is supplied from the hydrogen chloride gas supply source 2614, and a flow rate of the hydrogen chloride gas is controlled by the MFC 24144. Then, the hydrogen chloride gas is introduced into the seventh nozzle 2307 through the fourth gas supply pipe 824 and the seventh gas supply pipe 827, and into the processing chamber 201 through the seventh gas supply port 937. Also, the valve 5210 and the valve 529 are opened, an inert gas is supplied from the inert gas supply source 2617 to the third vaporizer 2417, and a TMAl source is vaporized by the third vaporizer 2417. Then, the TMAl gas is introduced into the seventh nozzle 2307 through the seventh gas supply pipe 827, and into the processing chamber 201 through the seventh gas supply port 937. That is, a mixed gas of hydrogen chloride gas and TMAl gas is supplied into the processing chamber 201 through the seventh gas supply port 937.

Also, the valve 524 and the valve 5245 are opened, hydrogen chloride gas is supplied from the hydrogen chloride gas supply source 2614, and a flow rate of the hydrogen chloride gas is controlled by the MFC 24145. Then, the hydrogen chloride gas is introduced into the eighth nozzle 2308 through the fourth gas supply pipe 824 and the eighth gas supply pipe 828, and into the processing chamber 201 through the eighth gas supply port 938. Also, the valve 5212 and the valve 5211 are opened, an inert gas is supplied from the inert gas supply source 2618 to the fourth vaporizer 2418, and a Cp₂Mg source is vaporized by the fourth vaporizer 2418. Then, the Cp₂Mg gas is introduced into the eighth nozzle 2308 through the eighth gas supply pipe 828, and into the processing chamber 201 through the eighth gas supply port 938. That is, a mixed gas of hydrogen chloride gas and Cp₂Mg gas is supplied into the processing chamber 201 through the eighth gas supply port 938.

The hydrogen chloride gas and the TMGa gas are subjected to a chemical reaction such as decomposition in the processing chamber 201, thereby forming gallium chloride (GaCl₃) gas. Then, the magnesium-doped aluminum gallium nitride film 2007 is formed on the aluminum gallium nitride layer 2006 arranged on the wafer 200 by reaction of the gallium chloride gas, the ammonia gas and the TMAl gas.

Also, when the ammonia gas and the TMGa gas are supplied into the processing chamber 201 at a flow rate ratio of 1:10 to 1:50, a magnesium-doped aluminum gallium nitride film may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, a magnesium-doped aluminum gallium nitride film may be more readily formed to a uniform film thickness on a surface of the wafer 200 held at a lower end of the boat 217, and a magnesium-doped aluminum gallium nitride film may be readily formed to a uniform film thickness on each of the substrates arranged at the entire substrate processing region.

This gallium nitride film-forming process has the same effect as at least one of the plurality of effects described in the description of the underlying buffer film-forming process and the barrier film-forming process, and also has at least one of a plurality of effects, which are described below.

1) Since the chlorine-containing gas is supplied into the eighth nozzle 2308, deposition of a magnesium ingredient or a magnesium-containing material in the eighth nozzle 2308 may be prevented by etching due to a chlorine ingredient even when the magnesium-containing gas is subjected to a chemical reaction such as decomposition, and the aluminum ingredient or the aluminum-containing material is generated in the eighth nozzle 2308.

2) Since the Cp₂Mg gas serving as the magnesium-containing gas is supplied through the eighth gas supply port 938 arranged at the heat-insulating region 2061, the Cp₂Mg gas is previously heated at the heat-insulating region 2061 prior to reaching the substrate processing region 2062, and the Cp₂Mg gas reacts by heat energy, thereby facilitating a reaction such as decomposition of a magnesium ingredient. Therefore, magnesium atoms may be easily uniformly penetrated into the aluminum gallium nitride film in a surface of the wafer 200 held at a lower end of the boat 217, and uniform distribution of the magnesium atoms in the aluminum gallium nitride film may be easily achieved in the surface of the wafer 200. Accordingly, an aluminum gallium nitride film in which the magnesium atoms are uniformly distributed may be more easily formed at each of the substrates arranged at the entire substrate processing region.

3) Since the Cp₂Mg gas serving as the magnesium-containing gas is provided closer to the substrate processing region than the first gas supply port 931 configured to introduce ammonia gas into the processing chamber 201, the fifth gas supply port 935 configured to introduce a mixed gas of hydrogen chloride gas and TMGa gas into the processing chamber 201, and the seventh gas supply port 937 configured to introduce a mixed gas of hydrogen chloride gas and TMAl gas into the processing chamber 201, these gases may be mixed, or the Cp₂Mg gas may be introduced in a chemically reactive atmosphere. As a result, the reaction efficiency of these gases may be improved.

4) Since the eighth nozzle 2308 and the eighth gas supply port 938 are installed at the heat-insulating region 2061, overheating of the eighth nozzle 2308 or a vicinity of the eighth gas supply port 938 is prevented. Therefore, a magnesium ingredient generated by pyrolysis of the Cp₂Mg gas serving as the magnesium-containing gas in the eighth nozzle 2308 or around the eighth gas supply port 938, or a gallium-containing material such as gallium chloride generated by reaction of the ammonia gas and the gallium chloride gas may be prevented from being attached to or deposited on the eighth nozzle 2308 or the vicinity of the eighth gas supply port 938. That is, unnecessary consumption of the magnesium atoms may be prevented, and an aluminum gallium nitride film having a uniform film thickness and doped with magnesium atoms may be effectively formed on the wafer 200, and closing of an inside of the eighth nozzle 2308 or the eighth gas supply port 938 may be prevented.

Preferably, the eighth gas supply port 938 becoming an upper end of the eighth nozzle 2308 is the heat-insulating region 2061, and may be installed at a higher position than a vertical position of a lower end of a heating element of the heating device 206d. Therefore, the hydrogen chloride gas and the TMGa gas may be further previously heated prior to reaching the substrate processing region 2062, and reaction of the hydrogen chloride gas and the TMGa gas and reaction of the gallium chloride and the ammonia gas may also be facilitated at the same time. Also, a gallium nitride film may be more effectively formed on the wafer 200, and closing of the inside of the fifth nozzle 2305 and the fifth gas supply port 935 may be prevented.

Also in this process, like the above-described barrier film-forming process, as a gas which is mixed with the TMAl gas in the seventh gas nozzle 2307, chlorine gas and hydrogen gas may be used instead of the hydrogen chloride gas.

Also, as a gas which is mixed with the Cp₂Mg gas in the eighth gas nozzle 2308, chlorine gas and hydrogen gas may be used instead of the hydrogen chloride gas. For example, when the hydrogen chloride gas supply source 2614 is exchanged with a chlorine gas supply source, the supply of the chlorine gas and the hydrogen gas may be controlled as follows. The valve 524 and the valve 5245 are opened, a flow rate of chlorine gas supplied from the chlorine gas supply source is controlled by the MFC 24145, and the chlorine gas is introduced into the eighth nozzle 2308 through the fourth gas supply pipe 824 and the eighth gas supply pipe 828, and into the processing chamber 201 through the eighth gas supply port 938. Also, the valve 522 and the valve 5225 are opened, a flow rate of hydrogen gas supplied from the hydrogen gas supply source 2412 is controlled by the MFC 24125, and the hydrogen gas is introduced into the eighth nozzle 2308 through the second gas supply pipe 822 and the eighth gas supply pipe 828, and into the processing chamber 201 through the eighth gas supply port 938. Also, the valve 5212 and the valve 5211 are opened, an inert gas supplied from the inert gas supply source 2418 is supplied to the fourth vaporizer 2418, and a Cp₂Mg source is vaporized by the fourth vaporizer 2418, introduced into the eighth nozzle 2308 through the eight gas supply pipe 828, and introduced into the processing chamber 201 through the eighth gas supply port 938. That is, a mixed gas of chlorine gas, hydrogen gas and Cp₂Mg gas may be controlled so that the mixed gas may be supplied into the processing chamber 201 through the eighth gas supply port 938.

Also in this process, like the above-described barrier film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied.

Also in this process, like the above-described barrier film-forming process, a hydrogen gas supply source may be installed instead of the inert gas supply source 2617.

Also in this process, a hydrogen gas supply source may be installed instead of the above-described inert gas supply source 2618. That is, hydrogen gas may be used as a gas for vaporizing the Cp₂Mg source.

(Cap Film-Forming Process)

Next, as shown in FIG. 2, a P-type-doped gallium nitride layer, that is, a magnesium-doped gallium nitride (Mg-Doped GaN) layer 2008 which is a P-type semiconductor film serving as a cap film, is formed on the magnesium-doped aluminum gallium nitride layer 2007. In a state where a temperature in the processing chamber 201 is stably maintained at a predetermined temperature of 900° C. to 1100° C., and a pressure in the processing chamber 201 is stably maintained at a predetermined pressure of 66 Pa to 13,330 Pa, and preferably a pressure of 66 Pa to 1,333 Pa, ammonia gas serving as the nitrogen-containing gas, TMGa gas serving as the gallium-containing gas, hydrogen chloride gas serving as the chlorine-containing gas, and bis(cyclopentadienyl) magnesium (Cp₂Mg) gas, which is a magnesium-containing gas, serving as a magnesium (Mg) dopant gas are supplied into the processing chamber 201, and a magnesium-doped gallium nitride film 2008 serving as a magnesium-containing gallium nitride film is formed on the wafer 200.

Specifically, as shown in FIG. 1, when the valve 521 and the valve 5211 continue to be open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935.

Also, the valve 524 and the valve 5245 are opened, hydrogen chloride gas is supplied from the hydrogen chloride gas supply source 2614, and a flow rate of the hydrogen chloride gas is controlled by the MFC 24145. Then, the hydrogen chloride gas is introduced into the eighth nozzle 2308 through the fourth gas supply pipe 824 and the eighth gas supply pipe 828, and into the processing chamber 201 through the eighth gas supply port 938. Also, the valve 5212 and the valve 5211 are opened, an inert gas is supplied from the inert gas supply source 2618 to the fourth vaporizer 2418, and a Cp₂Mg source is vaporized by the fourth vaporizer 2418. Then, the Cp₂Mg gas is introduced into the eighth nozzle 2308 through the eighth gas supply pipe 828, and into the processing chamber 201 through the eighth gas supply port 938. That is, a mixed gas of hydrogen chloride gas and Cp₂Mg gas is supplied into the processing chamber 201 through the eighth gas supply port 938.

The hydrogen chloride gas and the TMGa gas are subjected to a chemical reaction such as decomposition in the processing chamber 201, thereby forming gallium chloride (GaCl₃) gas. Then, the magnesium-doped gallium nitride film 2008 is formed on the magnesium-doped aluminum gallium nitride layer 2007 arranged on the wafer 200 by reaction of the gallium chloride gas, the ammonia gas and the Cp₂Mg gas.

Also, when the ammonia gas and the TMGa gas are supplied into the processing chamber 201 at a flow rate ratio of 1:10 to 1:50, a magnesium-doped gallium nitride film may be more readily formed to a uniform film thickness on a surface of the wafer 200 held at a lower end of the boat 217, and a film may be readily formed to a uniform film thickness on each of the substrates arranged at the entire substrate processing region. More preferably, when the TMGa gas and the hydrogen chloride gas are supplied into the processing chamber 201 at a flow rate ratio of 1:2 to 1:5, a magnesium-doped gallium nitride film may be more readily formed to a uniform film thickness on a surface of the wafer 200 held at a lower end of the boat 217, and a magnesium-doped gallium nitride film may be readily formed to a uniform film thickness on each of the substrates arranged at the entire substrate processing region.

This process has the same effect as at least one of the plurality of effects described in the description of the underlying buffer film-forming process and the P-type semiconductor film-forming process, and also has at least one of a plurality of effects, which are described below.

1) Since an underlying buffer film, a gallium nitride epitaxial film, an N-type semiconductor film, a light-emitting film, a barrier film, a P-type semiconductor film and a cap film may be formed on a substrate in the same processing chamber without unloading the substrate from the processing chamber, a high-quality stacked layer may be formed without interposing the impurities or native oxide film between the respective films, thereby improving throughput.

According to the present invention, like the above-described P-type semiconductor film-forming process, as a gas which is mixed with the Cp₂Mg gas in the eighth gas nozzle 2308, chlorine gas and hydrogen gas may also be used instead of the hydrogen chloride gas.

Also in this process, like the above-described P-type semiconductor film-forming process, a mixed gas of ammonia gas, hydrogen gas and nitrogen gas, a mixed gas of a nitrogen-containing gas such as nitrogen gas and a hydrogen-containing gas such as hydrogen gas, or other nitrogen- and hydrogen-containing gases may be supplied instead of the supply of ammonia gas. Also, a mixed gas of a chlorine-containing gas such as chlorine gas and a hydrogen-containing gas such as hydrogen gas, or other chlorine- and hydrogen-containing gases may be used instead of the hydrogen chloride gas. Also, a mixed gas of TMGa gas, hydrogen chloride gas, hydrogen gas and nitrogen gas, a mixed gas of TMGa gas, hydrogen gas and nitrogen gas, a mixed gas of TMGa gas, chlorine gas and hydrogen gas, or a mixed gas of TMGa gas, chlorine gas, hydrogen gas and nitrogen gas may be supplied instead of the mixed gas of TMGa gas and hydrogen chloride gas. Also, a gallium-containing gas such as gallium chloride (GaCl₃) gas may be used instead of the TMGa gas, and a mixed gas of gallium chloride gas and hydrogen chloride gas, a mixed gas of gallium chloride gas, hydrogen chloride gas, hydrogen gas and chlorine gas, a mixed gas of gallium chloride gas, hydrogen gas and chlorine gas, or a mixed gas of gallium chloride gas, hydrogen gas, chlorine gas and nitrogen gas may be supplied.

Also in this process, like the above-described P-type semiconductor film-forming process, a hydrogen gas supply source may be installed instead of the inert gas supply source 2618.

(Boat-Unloading Process)

When a preset time lapses in the cap film-forming process, the valve 523 and the valve 5231 are opened, an inert gas is supplied from the inert gas supply source 2613, and a flow rate of the inert gas is controlled by the MFC 24131. Then, the inert gas is introduced into the first nozzle 2301 through the third gas supply pipe 823 and the first gas supply pipe 821, and into the processing chamber 201 through the first gas supply port 931. The inside of the processing chamber 201 is filled with the inert gas, and a pressure in the processing chamber 201 returns to a normal pressure.

Then, as the seal cap 219 is lowered by the boat elevator 115, a lower end of the manifold 209 is opened, and the processed wafer 200 is unloaded from the process tube 203 (inner tube 203) from a lower end of the manifold 209 in a state where the processed wafer 200 is held by the boat 217 (boat unloading). Then, the processed wafer 200 is discharged from the boat 217 (wafer discharging).

Subsequently, the processed wafer 200 is accommodated in a substrate accommodating unit such as a cassette or a pod in the substrate processing apparatus 101, and every substrate accommodating unit is unloaded from the substrate processing apparatus 101.

Also in a series of processes spanning from the above-described boat-loading process to the boat-unloading process, various combinations and applications are possible. For example, the boat-loading process may be performed without performing the other film-forming processes after the underlying buffer film-forming process, and the boat-loading process may be performed without performing the other film-forming processes after the underlying buffer film-forming process and the gallium nitride epitaxial film-forming process. Also, one of the underlying buffer film-forming process, the gallium nitride epitaxial film-forming process, the N-type semiconductor film-forming process, the light-emitting film-forming process, the barrier film-forming process, the P-type semiconductor film-forming process and the cap film-forming process may be performed between the boat-loading process and the boat-unloading process, and a combination of the plurality of processes may be performed.

In this case, the first gas supply system 811 to the ninth gas supply system 819 or various components constituting the first gas supply system 811 to the ninth gas supply system 819 may not be installed, when necessary.

### Second Embodiment

In the film-forming processes such as the underlying buffer film-forming process, the gallium nitride epitaxial film-forming process, the light-emitting film-forming process, the barrier film-forming process, the P-type semiconductor film-forming process and the cap film-forming process according to the above-described first embodiment, the ammonia gas is introduced into the processing chamber 201 through the first gas supply port 931 of the first nozzle 2301, and the TMGa gas and the hydrogen chloride gas are introduced into the processing chamber 201 through the fifth gas supply port 935 of the fifth nozzle 2305. According to this embodiment, gallium chloride gas generated by reaction of the ammonia gas or TMGa gas and the hydrogen chloride gas may not reach central portions of the wafers 200 stacked in plural numbers, and a Ga ingredient is present at a lower amount in a film of a central portion of the wafer 200 than a circumferential portion of the wafer 200, or a film becomes thinner. In order to solve this problem, in this second embodiment, when the ammonia gas is introduced into the processing chamber 201 through the first gas supply port 931 of the first nozzle 2301, and the TMGa gas and the hydrogen chloride gas are introduced into the processing chamber 201 through the fifth gas supply port 935 of the fifth nozzle 2305, nitrogen gas or hydrogen gas serving as the inert gas which is a carrier gas is introduced into the processing chamber 201 through the ninth gas supply port 939 of the ninth nozzle 2309. Therefore, the substrate processing region 2062 is configured so that a Ga ingredient can easily reach the central region of the wafer 200 from a circumference of the wafer 200.

Specifically, as shown in FIG. 1, when the valve 521 and the valve 5211 are kept open, ammonia gas is supplied from the ammonia gas supply source 2611, and a flow rate of the ammonia gas is controlled by the MFC 2411. Then, the ammonia gas is introduced into the first nozzle 2301 through the first gas supply pipe 821, and into the processing chamber 201 through the first gas supply port 931.

Also, the valve 524 and the valve 5242 are opened, hydrogen chloride gas is supplied from the hydrogen chloride gas supply source 2614, and a flow rate of the hydrogen chloride gas is controlled by the MFC 24142. Then, the hydrogen chloride gas is introduced into the fifth nozzle 2305 through the fourth gas supply pipe 824 and the fifth gas supply pipe 825, and into the processing chamber 201 through the fifth gas supply port 935. Also, the valve 526 and the valve 525 are opened, an inert gas is supplied from the inert gas supply source 2615 to the first vaporizer 2415, and a TMGa source is vaporized by the first vaporizer 2415. Then, the TMGa gas is introduced into the fifth nozzle 2305 through the fifth gas supply pipe 825, and into the processing chamber 201 through the fifth gas supply port 935. That is, a mixed gas of hydrogen chloride gas and TMGa gas is supplied into the processing chamber 201 through the fifth gas supply port 935. At this time, in a state where the valve 5213 and the valve 52131 are closed, the valve 522 and the valve 5226 are opened, hydrogen gas is supplied from the hydrogen gas supply source 2612, and a flow rate of the hydrogen gas is controlled by the MFC 24126. Then, the hydrogen gas is introduced into the ninth nozzle 2309 through the ninth gas supply pipe 829, and into the processing chamber 201 through the ninth gas supply port 939.

The hydrogen chloride gas and the TMGa gas are subjected to a chemical reaction such as decomposition in the processing chamber 201, thereby forming gallium chloride (GaCl₃) gas. Then, the Ga ingredient may be allowed to easily reach the central portion of the wafer 200 by reaction of the gallium chloride gas, the ammonia gas and the dichlorosilane gas, or by the supply of hydrogen gas as the carrier gas through the ninth gas supply port 939, and thus a large amount of a Ga ingredient may be present in a film of the central portion of the wafer 200, or a thicker film may be formed in the central portion. That is, as the carrier gas is supplied between the wafers 200 through the ninth gas supply port 939 arranged at the circumference of the wafer 200, the Ga ingredient is carried between the wafers 200. As a result, in-plane uniformity of film quality or film thickness of the wafer 200 may be improved. Also, the amount of the Ga ingredient may be excessively increased in the central portion of the wafer 200 by the supply of the carrier gas through the ninth gas supply port 939. At this time, the in-plane uniformity of film quality or film thickness of the wafer 200 is rather degraded. In this case, the supply of the carrier gas through the ninth gas supply port 939 may be performed intermittently. At a time when the carrier gas is supplied through the ninth gas supply port 939, the Ga ingredient may easily reach the central portion of the wafer 200. Meanwhile, at a time when the carrier gas is not supplied through the ninth gas supply port 939, the Ga ingredient may easily reach the circumferential portion of the wafer 200. Through this action, the in-plane uniformity of film quality or film thickness of the wafer 200 may be improved by intermittently supplying the carrier gas through the ninth gas supply port 939.

Also, as the carrier gas, nitrogen gas serving as the inert gas may be used instead of the hydrogen gas. In this case, when the valve 5213 and the valve 52131 are kept closed, the valve 523 and the valve 5236 are opened, an inert gas is supplied from the inert gas supply source 2613, and a flow rate of the inert gas is controlled by the MFC 24136. Then, the inert gas may be introduced into the ninth nozzle 2309 through the ninth gas supply pipe 829, and into the processing chamber 201 through the ninth gas supply port 939. Also, this embodiment describes that the inert gas is supplied through the ninth gas supply port 939 of the ninth nozzle 2309, but such nozzles may be separately installed instead of the ninth nozzle 2300, and the inert gas may be supplied through a gas supply port installed at the separate nozzle. That is, a nozzle, which extends in a vertical direction with respect to a sidewall of the manifold 209, is installed to bend upward and extend to an upper end of the substrate processing region, and has a closed upper end and a plurality of (for example, many) ninth gas supply ports installed at a sidewall thereof, may be installed as the separate nozzle.

### Third Embodiment

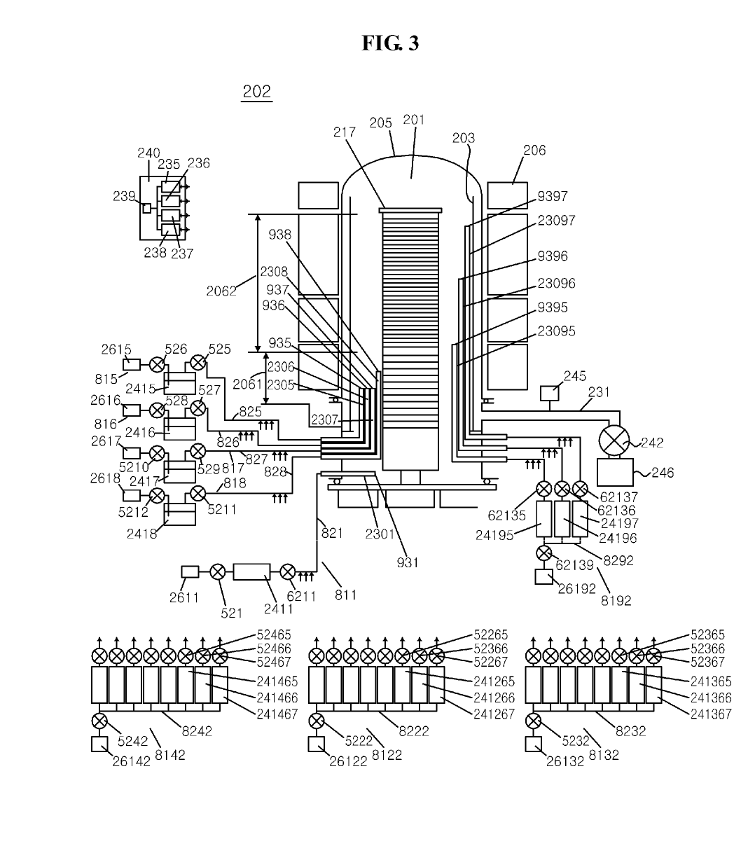

FIG. 3 shows a configuration according to a third embodiment. This embodiment is different from the first embodiment in that the ninth gas supply system is generally provided with a plurality of nozzles that have different lengths and extend to the substrate processing region 2062, instead of the nozzle that is installed to extend to the upper end of the substrate processing region, and has a closed upper end and a plurality of (for example, many) ninth gas supply ports installed at a sidewall thereof.

Specifically, as shown in FIG. 3, a tenth nozzle 23095, an eleventh nozzle 23096 and a twelfth nozzle 23097 are provided as the ninth gas supply system 8192.

Each of the tenth nozzle 23095, the eleventh nozzle 23096 and the twelfth nozzle 23097 is installed to extend from one end side, that is, a lower end side, of the inside of the processing chamber 201 to the substrate processing region 2062. The tenth nozzle 23095, the eleventh nozzle 23096 and the twelfth nozzle 23097 are installed to extend in a vertical direction with respect to a sidewall of the manifold 209, and bend upward and extend at different lengths to the substrate processing region. The tenth nozzle 23095 is installed to be shorter than the eleventh nozzle 23096, and the eleventh nozzle 23097 is installed to extend to a higher position than the tenth nozzle 23095. Also, the eleventh nozzle 23096 is installed to be shorter than the twelfth nozzle 23097, and the twelfth nozzle 23097 is installed to extend to a higher position than the eleventh nozzle 23096. Each of the tenth nozzle 23095, the eleventh nozzle 23096 and the twelfth nozzle 23097 has an open front end, and a tenth gas supply port 9395, an eleventh gas supply port 9396 and a twelfth gas supply port 9397 are formed at the tenth nozzle 23095, the eleventh nozzle 23096 and the twelfth nozzle 23097, respectively.

The tenth nozzle 23095 is connected to a ninth gas supply pipe 8292. To an upstream side of the ninth gas supply pipe 8292 which is opposite to a contact side of the tenth nozzle 23095, an MFC 24195 serving as the gas flow rate control unit is connected via a valve 62135 serving as a thirteenth opening/closing body 12. An upstream side of the ninth gas supply pipe 8292 which is opposite to a contact side of the MFC 24195 is connected to a silicon (Si)-containing gas supply source 26192 via a valve 62139 serving as a thirteenth opening/closing body-11.

The eleventh nozzle 23096 is connected to the ninth gas supply pipe 8292. To an upstream side of the ninth gas supply pipe 8292 which is opposite to a contact side of the eleventh nozzle 23096, an MFC 24196 serving as a gas flow rate control unit is connected via a valve 62136 serving as a thirteenth opening/closing body-13. An upstream side of the ninth gas supply pipe 8292 which is opposite to a contact side of the MFC 24196 is connected between the MFC 24195 and the valve 62139. That is, the upstream side of the ninth gas supply pipe 8292 which is opposite the contact side of the MFC 24196 is connected to the silicon (Si)-containing gas supply source 26192 via the valve 62139.

The twelfth nozzle 23097 is connected to the ninth gas supply pipe 8292. To an upstream side of the ninth gas supply pipe 8292 which is opposite to a contact side of the twelfth nozzle 23097, an MFC 24197 serving as a gas flow rate control unit is connected via a valve 62137 serving as a thirteenth opening/closing body-14. An upstream side of the ninth gas supply pipe 8292 which is opposite to a contact side of the MFC 24197 is connected between the MFC 24195 and the valve 62139. That is, the upstream side of the ninth gas supply pipe 8292 which is opposite to the contact side of the MFC 24197 is connected to the silicon (Si)-containing gas supply source 26192 via the valve 62139.

A second gas supply pipe 8222 is connected between the tenth nozzle 23095 and the valve 62135 of the ninth gas supply pipe 8292. To an upstream side of the second gas supply pipe 8222 which is opposite to a contact side of the ninth gas supply pipe 8292, an MFC 241265 serving as a gas flow rate control unit is connected via a valve 52265 serving as a second opening/closing body-4. An upstream side of the second gas supply pipe 8222 which is opposite to a contact side of the MFC 241265 is connected to a hydrogen gas supply source 26122 via the valve 5222.

A third gas supply pipe 8232 is connected between the tenth nozzle 23095 and the valve 62135 of the ninth gas supply pipe 8292. To an upstream side of the third gas supply pipe 8232 which is opposite to a contact side of the ninth gas supply pipe 8292, an MFC 241365 serving as a gas flow rate control unit is connected via a valve 52365 serving as a third opening/closing body-4. An upstream side of the third gas supply pipe 8232 which is opposite to a contact side of the MFC 241365 is connected to an inert gas supply source 26132 via the valve 5232.

A fourth gas supply pipe 8242 is connected between the tenth nozzle 23095 and the valve 62135 of the ninth gas supply pipe 8292. To an upstream side of the fourth gas supply pipe 8242 which is opposite to a contact side of the ninth gas supply pipe 8292, an MFC 241465 serving as a gas flow rate control unit is connected via a valve 52465 serving as a fourth opening/closing body 4. An upstream side of the fourth gas supply pipe 8242 which is opposite to a contact side of the MFC 241465 is connected to a hydrogen chloride gas supply source 26142 via the valve 5242.

The second gas supply pipe 8222 is connected between the eleventh nozzle 23096 and the valve 62136 of the ninth gas supply pipe 8292. To an upstream side of the second gas supply pipe 8222 which is opposite to a contact side of the ninth gas supply pipe 8292, an MFC 241266 serving as a gas flow rate control unit is connected via a valve 52266 serving as a second opening/closing body-5. An upstream side of the second gas supply pipe 8222 which is opposite to a contact side of the MFC 241266 is connected to the hydrogen gas supply source 26122 via the valve 5222.

The third gas supply pipe 8232 is connected between the eleventh nozzle 23096 and the valve 62136 of the ninth gas supply pipe 8292. To an upstream side of the third gas supply pipe 8232 which is opposite to a contact side of the ninth gas supply pipe 8292, an MFC 241366 serving as a gas flow rate control unit is connected via a valve 52366 serving as a third opening/closing body-5. An upstream side of the third gas supply pipe 8232 which is opposite to a contact side of the MFC 241366 is connected to the inert gas supply source 26132 via the valve 5232.

The fourth gas supply pipe 8242 is connected between the eleventh nozzle 23096 and the valve 62136 of the ninth gas supply pipe 8292. To an upstream side of the fourth gas supply pipe 8242 which is opposite to a contact side of the ninth gas supply pipe 8292, an MFC 241466 serving as a gas flow rate control unit is connected via a valve 52466 serving as a fourth opening/closing body-5. An upstream side of the fourth gas supply pipe 8242 which is opposite to a contact side of the MFC 241466 is connected to the hydrogen chloride gas supply source 26142 via the valve 5242.

The second gas supply pipe 8222 is connected between the twelfth nozzle 23097 and the valve 62137 of the ninth gas supply pipe 8292. To an upstream side of the second gas supply pipe 8222 which is opposite to a contact side of the ninth gas supply pipe 8292, an MFC 241267 serving as a gas flow rate control unit is connected via a valve 52267 serving as a second opening/closing body-6. An upstream side of the second gas supply pipe 8222 which is opposite to a contact side of the MFC 241267 is connected to the hydrogen gas supply source 26122 via the valve 5222.

The third gas supply pipe 8232 is connected between the twelfth nozzle 23097 and the valve 62137 of the ninth gas supply pipe 8292. To an upstream side of the third gas supply pipe 8232 which is opposite to a contact side of the ninth gas supply pipe 8292, an MFC 241367 serving as a gas flow rate control unit is connected via a valve 52367 serving as a third opening/closing body-6. An upstream side of the third gas supply pipe 8232 which is opposite to a contact side of the MFC 241367 is connected to the inert gas supply source 26132 via the valve 5232.

The fourth gas supply pipe 8242 is connected between the twelfth nozzle 23097 and the valve 62137 of the ninth gas supply pipe 8292. To an upstream side of the fourth gas supply pipe 8242 which is opposite to a contact side of the ninth gas supply pipe 8292, an MFC 241467 serving as a gas flow rate control unit is connected via a valve 52467 serving as a fourth opening/closing body 6. An upstream side of the fourth gas supply pipe 8242 which is opposite to a contact side of the MFC 241467 is connected to the hydrogen chloride gas supply source 26142 via the valve 5242.

In this configuration, when gases are respectively supplied through the tenth gas supply port 9395 of the tenth nozzle 23095, the eleventh gas supply port 9396 of the eleventh nozzle 23096 and the twelfth gas supply port 9397 of the twelfth nozzle 23097, instead of being supplied through the ninth gas supply port 939 of the ninth nozzle 2309 in the film-forming processes such as the underlying buffer film-forming process, the gallium nitride epitaxial film-forming process, the light-emitting film-forming process, the barrier film-forming process, the P-type semiconductor film-forming process and the cap film-forming process as described above in the first and second embodiments, the same effects as described in the first and second embodiments may be achieved.

### Other Embodiments

In the other embodiments, the ninth nozzle 2309 described in the first and second embodiments, and the tenth nozzle 9395, the eleventh nozzle 9396 and the twelfth nozzle 9397 described in the third embodiment may be all configured to be installed.

As described above, the present invention is characterized by the contents set forth in the scope of the claims, but may further include embodiments as follows.

### First Embodiment

A method of forming a film including:

loading a plurality of substrates into a substrate processing region in a processing chamber; and

forming a film containing nitrogen and metal on each of the plurality of substrates by heating the substrate processing region in the processing chamber, supplying a nitrogen-containing gas through a first gas supply port installed outside the substrate processing region in the processing chamber, and supplying a metal-containing gas through a second gas supply port installed closer to the substrate processing region than the first gas supply port.

### Second Embodiment

The method of forming a film according to the first embodiment, wherein, in forming the film containing nitrogen and metal, an inert gas is supplied from a circumferential side portion of each of the plurality of substrates within the substrate processing region in the processing chamber.

### Third Embodiment

The method of forming a film according to the second embodiment, wherein the inert gas is intermittently supplied from the circumferential side portion of each of the plurality of substrates.

### Fourth Embodiment

A method of forming a film, including:

loading a plurality of substrates into a substrate processing region in a processing chamber; and

forming a film containing silicon, nitrogen and metal on each of the plurality of substrates by heating of the substrate processing region in the processing chamber, supplying a nitrogen-containing gas and a metal-containing gas from an outside of the substrate processing region in the processing chamber, and supplying a silicon-containing gas from an inside of the substrate processing region in the processing chamber.

### Fifth Embodiment

A method of forming a film, including:

loading a substrate-holding unit into a processing chamber in a state where a plurality of substrates are stacked and held at predetermined intervals in a vertical direction with respect to a main surface of the substrates; and

forming a film containing silicon, nitrogen metal on each of the plurality of substrates held by the substrate-holding unit by maintaining heating of a first region in which the plurality of substrates in the processing chamber are held to a preset temperature, supplying a nitrogen-containing gas into the processing chamber from a first gas supply unit arranged inside the processing chamber and arranged outside the first region in the processing chamber, supplying a metal element-containing gas into the processing chamber from a second gas supply unit installed closer to the first region in the processing chamber than a position at which the nitrogen-containing gas is supplied from the first gas supply unit installed inside the processing chamber, and supplying a silicon-containing gas into the processing chamber from a third gas supply unit arranged in the first region as an inside of the processing chamber.

### Sixth Embodiment

A substrate processing apparatus including:

a processing chamber including a substrate processing region and configured to process a plurality of substrates at the substrate processing region;

a heating device configured to heat the substrate processing region;

a first gas supply system including a first gas supply port, the first gas supply port being configured to supply a nitrogen-containing gas into the processing chamber and installed outside the substrate processing region;

a second gas supply system including a second gas supply port, the second gas supply port being installed outside the substrate processing region while being closer to the substrate processing region than the first gas supply port and being configured to supply a metal-containing gas into the processing chamber; and

a control unit configured to control the heating device, the first gas supply system and the second gas supply system to form a film containing nitrogen and metal on each of a plurality of substrates in the substrate processing region by heating the substrate processing region, supplying the nitrogen-containing gas through the first gas supply port and supplying the metal-containing gas through the second gas supply port.

What is claimed is:

1. A method of forming a film, comprising:
loading a plurality of substrates into a substrate processing region in a processing chamber; and
forming a film containing nitrogen and metal on each of the plurality of substrates by heating the substrate processing region in the processing chamber, supplying a nitrogen-containing gas through a first gas supply port installed outside the substrate processing region in the processing chamber, and supplying a metal-containing gas through a second gas supply port installed closer to the substrate processing region than the first gas supply port.

2. The method according to claim 1, wherein, in forming the film containing nitrogen and metal, an inert gas is supplied from a circumferential side portion of each of the plurality of substrates within the substrate processing region in the processing chamber.

3. The method according to claim 2, wherein the inert gas is intermittently supplied from the circumferential side portion of each of the plurality of substrates.

4. A method of forming a film, comprising:
loading a plurality of substrates into a substrate processing region in a processing chamber; and
forming a film containing silicon, nitrogen and metal on each of the plurality of substrates by heating of the substrate processing region in the processing chamber, supplying a nitrogen-containing gas and a metal-containing gas from an outside of the substrate processing region in the processing chamber, and supplying a silicon-containing gas from an inside of the substrate processing region in the processing chamber.

5. A substrate processing apparatus comprising:
a processing chamber including a substrate processing region and configured to process a plurality of substrates at the substrate processing region;
a heating device configured to heat the substrate processing region;
a first gas supply system including a first gas supply port, the first gas supply port being configured to supply a nitrogen-containing gas into the processing chamber and installed outside the substrate processing region;
a second gas supply system including a second gas supply port, the second gas supply port being installed outside the substrate processing region while being closer to the substrate processing region than the first gas supply port and being configured to supply a metal-containing gas into the processing chamber; and
a control unit configured to control the heating device, the first gas supply system and the second gas supply system to form a film containing nitrogen and metal on each of a plurality of substrates in the substrate processing region by heating the substrate processing region, supplying the nitrogen-containing gas through the first gas supply port and supplying the metal-containing gas through the second gas supply port.
